(19) United States
(12) Patent Application Publication
(10) Pub. No.: US 2012/0235197 A1
(43) Pub. Date: Sep. 20, 2012

(54) ORGANIC EL DEVICE

(75) Inventor: Suguru OKUYAMA, Kyoto (JP)

(73) Assignee: ROHM CO., LTD., Kyoto (JP)

(21) Appl. No.: 13/417,220

(22) Filed: Mar. 10, 2012

(30) Foreign Application Priority Data
Mar. 10, 2011 (JP) 2011-052490
Jul. 1, 2011 (JP) 2011-147479
Jan. 20, 2012 (JP) 2012-010200

(51) Int. Cl. H01L 51/50

(52) U.S. Cl. 257/98; 257/E51.019

(57) ABSTRACT

An organic EL device includes a substrate, a first electrode layer arranged on the substrate, an organic EL layer arranged on the first electrode layer, an optical property adjusting layer arranged on the organic EL layer, and a second electrode layer arranged on the optical property adjusting layer.

### CROSS-REFERENCE TO RELATED APPLICATION(S)

This application is based upon and claims the benefit of priority from Japanese Patent Application Nos. 2012-10200, 2011-52490, and 2011-147479, filed on Jan. 20, 2012, Mar. 10, 2011, and Jul. 1, 2011, respectively, the entire contents of which are incorporated herein by reference.

### TECHNICAL FIELD

The present disclosure relates to an organic EL device and, more particularly, to an organic EL device capable of simultaneously optimizing the internal quantum efficiency and light extraction efficiency.

### BACKGROUND

In recent years, a display unit or a lighting unit using an organic EL (Electroluminescence) device (hereinafter, the term “organic EL Device” is also used interchangeably to refer to an “OLED (Organic Light Emitting Diode)”) as an organic light-emitting device has been developed for practical applications. In general, an organic EL device is manufactured by laminating, one above the next, a transparent electrode as an anode, an organic layer, and a metal electrode as a cathode on a transparent support substrate such as a glass substrate or a transparent plastic film.

Electrons supplied from the cathode and positive holes supplied from the anode are recombined within the organic layer as a voltage is applied between the transparent electrode and the metal electrode. As a result, excitons are generated and EL light is emitted when the excitons thus generated make a transition from an excited state to a ground state. The EL light is transmitted through the transparent substrate and is emitted from the transparent support substrate to the outside.

However, the organic EL device described above suffers from a problem in that the light generated in the organic layer cannot be sufficiently extracted to the outside.

### SUMMARY

The present disclosure provides some embodiments of an organic EL device capable of simultaneously optimizing the internal quantum efficiency and light extraction efficiency.

According to one aspect of the present disclosure, there is provided an organic EL device. The organic EL device includes a substrate, a first electrode layer arranged on the substrate, an organic EL layer arranged on the first electrode layer, an optical property adjusting layer arranged on the organic EL layer, and a second electrode layer arranged on the optical property adjusting layer.

According to another aspect of the present disclosure, there is provided an organic EL device. The organic EL device includes a substrate, a first electrode layer arranged on the substrate, an optical property adjusting layer arranged on the first electrode layer, an organic EL layer arranged on the optical property adjusting layer, and a second electrode layer arranged on the organic EL layer.

According to a yet another aspect of the present disclosure, there is provided an organic EL device. The organic EL device includes a substrate, a first electrode layer arranged on the substrate, an organic EL layer arranged on the first electrode layer, a second electrode layer arranged on the organic EL layer, and a high-refractive-index scattering layer arranged on the second electrode layer.

### BRIEF DESCRIPTION OF THE DRAWINGS

FIG. 1 is a schematic sectional view illustrating an organic EL device according to a first embodiment.

FIG. 2 is a schematic sectional view explaining an operation principle of carrier injection balance in an organic EL device according to a comparative example.

FIG. 3 is a schematic sectional view explaining an operation principle of light extraction efficiency in the organic EL device according to the comparative example.

FIG. 4 is a schematic sectional view explaining an operation principle of carrier injection balance in the organic EL device according to the first embodiment.

FIG. 5 is a schematic sectional view explaining an operation principle of light extraction efficiency in the organic EL device according to the first embodiment.

FIGS. 6A, 6B and 6C are schematic sectional views illustrating operation methods of the organic EL device according to the first embodiment. In particular, FIG. 6A illustrates an example in which a voltage is applied between a first electrode layer and a second electrode layer. FIG. 6B illustrates an example in which a voltage is applied between a first electrode layer and a property separation layer, and FIG. 6C illustrates an example in which a voltage is applied between a first electrode layer, a second electrode layer and a short-circuited property separation layer.

FIG. 7 is a schematic sectional view illustrating an organic EL device according to a second embodiment.

FIG. 8 is a schematic sectional view illustrating an organic EL device according to a third embodiment.

FIG. 9 is a schematic sectional view illustrating an organic EL device according to a modified example of the second embodiment.

FIG. 10 is a schematic sectional view illustrating an organic EL device according to a fourth embodiment.

FIGS. 11A through 11D are schematic plan pattern diagrams illustrating an optical property adjusting layer 24 in the organic EL device according to the fourth embodiment. In particular, FIG. 11A illustrates a circular pattern example, FIG. 11B illustrates a square pattern example, FIG. 11C illustrates a circular pattern example forming a triangle, and FIG. 11D illustrates a rectangular pattern example.

FIG. 12A is a schematic sectional view illustrating an organic EL device according to a first modified example of the fourth embodiment, and FIG. 12B is a schematic sectional view illustrating an organic EL device according to a second modified example of the fourth embodiment.

FIG. 13A is a schematic sectional view illustrating an organic EL device according to a third modified example of the fourth embodiment, and FIG. 13B is a schematic sectional view illustrating an organic EL device according to a fourth modified example of the fourth embodiment.

FIG. 14 is a schematic sectional view illustrating an organic EL device according to a fifth embodiment.

FIG. 15 is a schematic sectional view illustrating an organic EL device according to a sixth embodiment.

FIG. 16 is a schematic sectional view illustrating an organic EL device according to a seventh embodiment.

FIG. 17A is a schematic sectional view illustrating an organic EL device according to an eighth embodiment, FIG. 17B is a graph representing the relationship between a grain size distribution and a grain size and FIG. 17C is a schematic view illustrating grains existing in a polycrystalline organic material layer.

FIG. 18 is a schematic sectional view illustrating an organic EL device according to a ninth embodiment.

FIG. 19 is a schematic sectional view illustrating an organic EL device according to a tenth embodiment.

FIG. 20 is a schematic sectional view illustrating an organic EL device according to an eleventh embodiment.

FIG. 21 is a schematic sectional view illustrating an organic EL device according to a twelfth embodiment.

FIG. 22 is a schematic sectional view illustrating an organic EL device according to a thirteenth embodiment.

FIG. 23 is a schematic sectional view illustrating an organic EL device according to a fourteenth embodiment.

FIG. 24 is a schematic sectional view illustrating an organic EL device according to a fifteenth embodiment.

FIG. 25 is a schematic sectional view illustrating an organic EL device according to a sixteenth embodiment.

FIG. 26 is a schematic sectional view illustrating an organic EL device according to a seventeenth embodiment.

FIG. 27 is a schematic sectional view illustrating an organic EL device according to an eighteenth embodiment.

FIG. 28 is a schematic sectional view illustrating an organic EL device according to a nineteenth embodiment.

FIG. 29 is a schematic sectional view illustrating an organic EL device according to a twentieth embodiment.

FIG. 30 is a schematic sectional view illustrating an organic EL device according to a twenty-first embodiment.

FIG. 31 is a schematic sectional view illustrating an organic EL device according to a twenty-second embodiment.

FIG. 32 is a schematic sectional view illustrating an organic EL device according to a twenty-third embodiment.

FIG. 33 is a schematic sectional view illustrating an organic EL device according to a twenty-fourth embodiment.

FIG. 34 is a schematic sectional view illustrating an organic EL device according to a twenty-fifth embodiment.

FIG. 35 is a schematic sectional view illustrating an organic EL device according to a twenty-sixth embodiment.

FIG. 36 is a schematic sectional view illustrating an organic EL device according to a twenty-seventh embodiment.

FIG. 37 is a schematic sectional view illustrating an organic EL device according to a twenty-eighth embodiment.

FIG. 38 is a schematic sectional view illustrating an organic EL device according to a first modified example of the twenty-eighth embodiment.

FIG. 39 is a schematic sectional view illustrating an organic EL device according to a second modified example of the twenty-eighth embodiment.

FIG. 40 shows a chemical structural formula of 1,4-di(1,10-phenanthroline-2-yl) benzene (DPB).

FIG. 41 shows a chemical structural formula of 2-(4-tert-butylphenyl)-5-(4-biphenyl)-1,3,4-oxadiazole (PBD).

FIG. 42 shows a chemical structural formula of 2,5-bis(4-biphenylyl) thiophene (BP1T).

FIG. 43 shows a chemical structural formula of p-quaterphenyl(p-4P).

FIG. 44 shows a chemical structural formula of naphthalene-1,4,5,8-tetracarboxylic dianhydride (NTDA).

FIG. 45 is a schematic sectional view illustrating an organic EL device according to a twenty-ninth embodiment.

FIGS. 46A through 46D are schematic plan pattern diagrams illustrating a high-refractive-index scattering layer 34 in the organic EL device according to the twenty-ninth embodiment. In particular, FIG. 46A illustrates a circular pattern example, FIG. 46B illustrates a square pattern example, FIG. 46C illustrates a circular pattern example forming a triangle, and FIG. 46D illustrates a rectangular pattern example.

FIG. 47A is a schematic sectional view illustrating an organic EL device according to a first modified example of the twenty-ninth embodiment, and FIG. 47B is a schematic sectional view illustrating an organic EL device according to a second modified example of the twenty-ninth embodiment.

FIG. 48A is a schematic sectional view illustrating an organic EL device according to a third modified example of the twenty-ninth embodiment, and FIG. 48B is a schematic sectional view illustrating an organic EL device according to a fourth modified example of the twenty-ninth embodiment.

FIG. 49 is a schematic sectional view illustrating an organic EL device according to a thirtieth embodiment.

FIG. 50 is a schematic sectional view illustrating an organic EL device according to a thirty-first embodiment.

FIG. 51 is a schematic sectional view illustrating an organic EL device according to a thirty-second embodiment.

FIG. 52 is a schematic sectional view illustrating an organic EL device according to a thirty-third embodiment.

FIG. 53 is a schematic sectional view illustrating an organic EL device according to a thirty-fourth embodiment.

FIG. 54 is a schematic sectional view illustrating an organic EL device according to a thirty-fifth embodiment.

FIG. 55 is a schematic sectional view illustrating an organic EL device according to a first modified example of the thirty-fifth embodiment.

FIG. 56 is a schematic sectional view illustrating an organic EL device according to a second modified example of the thirty-fifth embodiment.

FIG. 57 is a schematic sectional view illustrating an organic EL device according to a third modified example of the thirty-fifth embodiment.

### DETAILED DESCRIPTION

Reference will be made in detail to various embodiments, examples of which are illustrated in the accompanying drawings. In the following detailed description, numerous specific details are set forth in order to provide a thorough understanding of the present invention(s). However, it will be apparent to one of ordinary skill in the art that the present invention(s) may be practiced without these specific details. In other instances, well-known methods, procedures, systems, and components have not been described in detail so as to not unnecessarily obscure aspects of the various embodiments.

The first through seventh embodiments of the present disclosure will now be described in detail with reference to the drawings. Throughout the drawings, identical or similar parts will be designated by identical or similar reference symbols. The drawings are schematic. It should be appreciated that the relationship between a thickness and a plane dimension and the ratios of thicknesses of individual layers differ from the actual ones. Accordingly, specific thicknesses and dimensions should be determined in light of the following description. It goes without saying that certain portions in the drawings differ in their relationship and ratio of dimensions from one another.

The first through seventh embodiments described below illustrate devices and methods embodying the technical concept of the present disclosure by way of example. These embodiments are not intended to limit the materials, shapes, structures and arrangements of individual components to the ones set forth below. These embodiments may be modified or changed in many different forms without departing from the scope of the present disclosure defined in the claims.

### First Embodiment

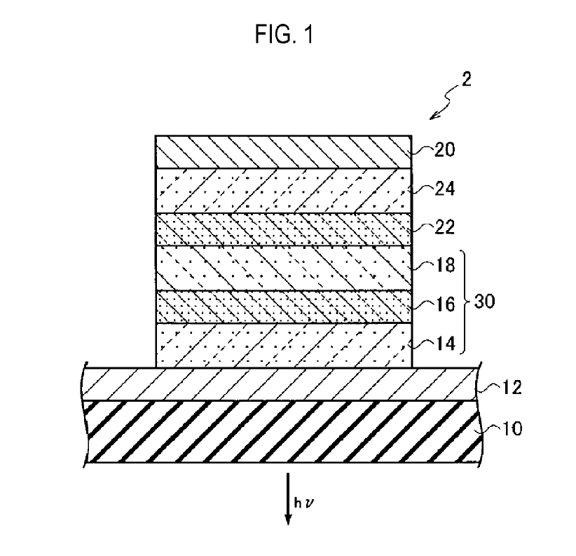

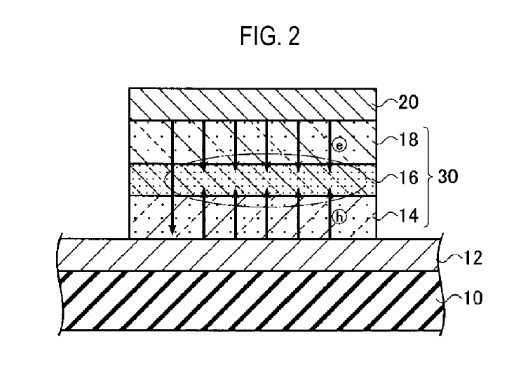

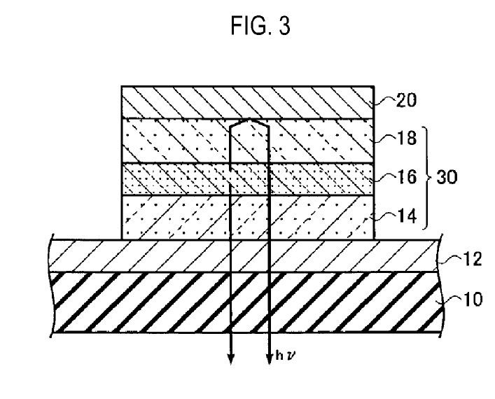

(Organic EL Device) A schematic cross-sectional structure of an organic EL device according to a first embodiment is shown in FIG. 1. A schematic cross-sectional structure for explaining an operation principle of carrier injection balance in an organic EL device according to a comparative example is shown in FIG. 2. Further, a schematic cross-sectional structure for explaining an operation principle of light extraction efficiency in the organic EL device according to the comparative example is shown in FIG. 3.

Referring to FIG. 1, an organic EL device 2 according to a first embodiment includes a substrate 10, a first electrode layer 12 arranged on the substrate 10, an organic EL layer 30 arranged on the first electrode layer 12, a property separation layer 22 arranged on the organic EL layer 30, an optical property adjusting layer 24 arranged on the property separation layer 22 and a second electrode layer 20 arranged on the optical property adjusting layer 24.

On the other hand, as shown in FIG. 2, an organic EL device according to a comparative example includes a substrate 10, a first electrode layer 12 as an anode electrode layer arranged on the substrate 10, an organic EL layer 30 arranged on the first electrode layer 12, and a second electrode layer 20 as a cathode electrode layer arranged on the organic EL layer 30.

In general, light emission efficiency is represented by the multiplication of the carrier injection balance by the exciton generation efficiency, radiation recombination probability of excitons, and light extraction efficiency. That is, light emission efficiency is represented by an equation: [light emission efficiency]=[carrier injection balance]×[exciton generation efficiency]×[radiation recombination probability of excitons]×[light extraction efficiency].

The carrier injection balance denotes the probability with which, as shown in FIG. 2, electrons (e) injected from the second electrode layer 20 and positive holes (h) injected from the first electrode layer 12 generate electron-hole pairs within a light emitting layer 16 in a well-balanced manner. Light emission loss occurs if no electron-hole pairs are generated within the light emitting layer 16 due to, e.g., the direct arrival of the electrons (e) at the first electrode layer 12.

The excitons generation efficiency denotes the probability or likelihood of the excitons being effectively generated in the light emitting layer 16. If the excitons are effectively generated in the light emitting layer 16 but fail to be recombined, then there will be light emission loss.

The carrier injection balance and exciton generation efficiency are decided by the electric properties, such as the electron mobility and hole mobility, within the respective layers of the organic EL layer, and the layer thickness.

The radiation recombination probability of excitons is a value that depends on the material used.

The light extraction efficiency denotes the probability with which, as shown in FIG. 3, the light emitted from the light emitting layer 16 (as direct light or light reflected by the interface between the second electrode layer 20 and the electron transport layer 18) is transmitted through the first electrode layer 12 and the substrate 10, and is emitted to the outside. A light emission loss occurs if the emitted light is canceled due to optical interference of the light emitted from the light emitting layer 16 with the light reflected by the interface between the second electrode layer 20 and the electron transport layer 18.

The light extraction efficiency is decided by the optical properties, such as the refractive index, within the respective layers of the organic EL layer, and the layer thickness.

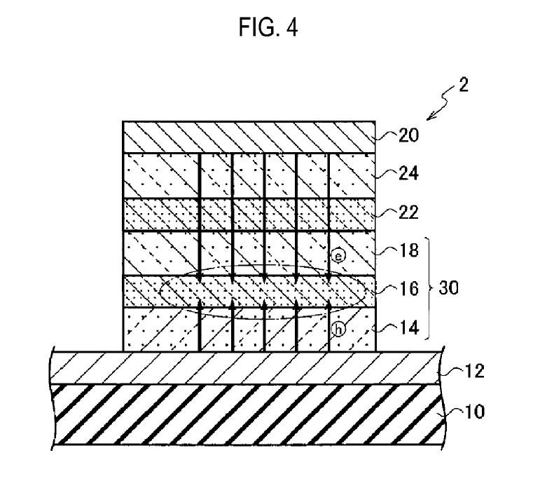

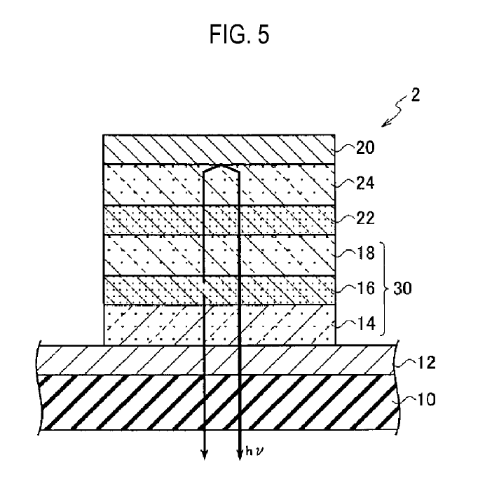

A schematic cross-sectional structure for explaining an operation principle of carrier injection balance in the organic EL device 2 according to the first embodiment is shown in FIG. 4. A schematic cross-sectional structure for explaining an operation principle of light extraction efficiency in the organic EL device 2 according to the first embodiment is shown in FIG. 5.

As shown in FIG. 4, the organic EL device 2 according to the first embodiment includes the property separation layer 22. This makes it possible to keep constant the carrier injection balance and exciton generation efficiency within the organic EL layer 30 arranged below the property separation layer 22. For example, even if the thickness of the optical property adjusting layer 24 is changed, the carrier injection balance within the organic EL layer 30 is barely changed. In other words, the carrier injection balance and exciton generation efficiency may be optimized by adjusting the thickness of the respective layers within the organic EL layer 30 arranged below the property separation layer 22. Consequently, it is possible to maximize the internal quantum efficiency.

As shown in FIG. 5, the organic EL device 2 according to the first embodiment includes the optical property adjusting layer 24. By adjusting the properties and thickness of the optical property adjusting layer 24, it is possible to adjust the optical properties and to enhance the light extraction efficiency. In other words, the optical interference may be optimized by adjusting the thickness of the optical property adjusting layer 24. As a result, it is possible to maximize the light extraction efficiency. Further, as stated above, even if the thickness of the optical property adjusting layer 24 is changed, the carrier injection balance within the organic EL layer 30 is kept constant.

In the manner described above, the internal quantum efficiency and the light extraction efficiency may be independently adjusted in the organic EL device 2 according to the first embodiment. It is therefore possible to readily maximize the final external quantum efficiency.

As described above, the organic EL device 2 according to the first embodiment includes the property separation layer 22 and the optical property adjusting layer 24. The optical properties may be independently adjusted by adjusting the properties and thickness of the optical property adjusting layer 24 while keeping constant the carrier injection balance and exciton generation efficiency within the organic EL layer 30 arranged below the property separation layer 22. Thus, it becomes easier to maximize the final external quantum efficiency.

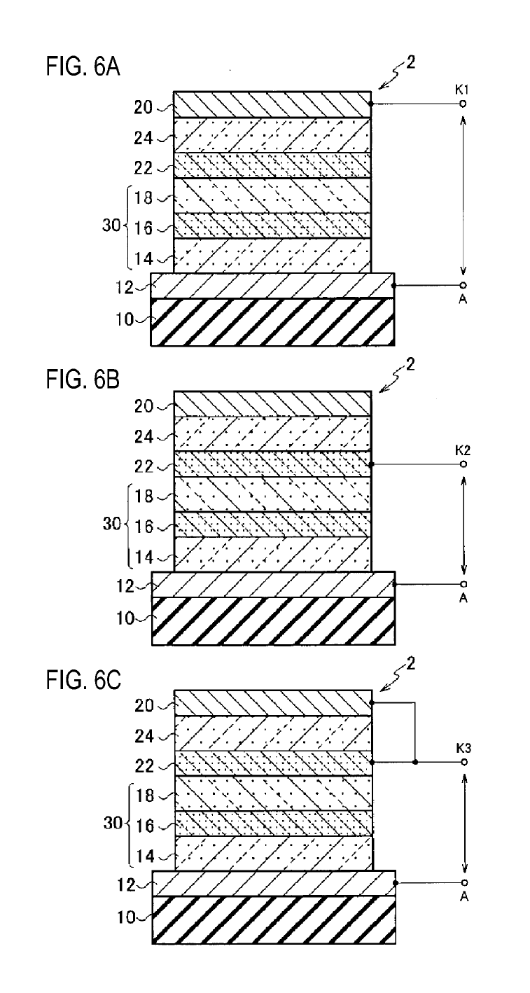

FIGS. 6A, 6B, and 6C are schematic sectional views illustrating operation methods of the organic EL device 2 according to the first embodiment. An example in which a voltage is applied between the first electrode layer 12 and the second electrode layer 20 is shown in FIG. 6A. An example in which a voltage is applied between the first electrode layer 12 and the property separation layer 22 is shown in FIG. 6B. An example in which a voltage is applied between the first electrode layer 12, and the second electrode layer 20 and the short-circuited property separation layer 22 is shown in FIG. 6C.

A method for selecting electrode terminals of the organic EL device 2 according to the first embodiment will now be explained with reference to the following figures. As shown in FIG. 6A, major electrodes may be selected from the first electrode layer 12 and the second electrode layer 20. As shown in FIG. 6B, major electrodes may be selected from the first electrode layer 12 and the property separation layer 22. As shown in FIG. 6C, major electrodes may be selected from the first electrode layer 12, the second electrode layer 20, and the short-circuited property separation layer 22.

The substrate 10 is a transparent substrate that allows light to pass therethrough. The substrate 10 may be formed of, e.g., a glass substrate or a plastic film with a gas barrier layer. The substrate 10 may have a thickness of, e.g., about 0.1 to 1.1 mm. In addition, the substrate 10 may be made flexible by forming the substrate 10 through the use of a transparent resin such as polycarbonate or polyethylene terephthalate (PET).

The first electrode layer 12 may be formed of an ITO (Indium Tin Oxide)-made transparent electrode having a thickness of, e.g., about 50 nm to 500 nm. Alternatively, the first electrode layer 12 may be made of IZO (Indium Zinc Oxide), ATO (Antimony Tin Oxide) or PEDOTT-PSS. Moreover, the first electrode layer 12 may be a translucent electrode formed of a thin film of metal such as Ag.

The organic EL layer 30 includes, e.g., a hole transport layer 14, a light emitting layer 16, and an electron transport layer 18, which are laminated one above another when viewed from the side of the substrate 10.

The hole transport layer 14 is a layer for smoothly transporting the positive holes injected from the first electrode layer 12 to the light emitting layer 16. The hole transport layer 14 may be made of, e.g., 4,4′-bis[N-(1-naphtyl-1-)N-phenyl-amino]-biphenyl.

The light emitting layer 16 is a layer for emitting light by recombining the injected positive holes and electrons. The light emitting layer 16 may be made of, e.g., aluminum (8-hydroxy) quinolinate doped with a dopant such as rubrene or a complex containing transition metal atoms.

The electron transport layer 18 is a layer for smoothly transporting the electrons injected from the second electrode layer 20 to the light emitting layer 16. The electron transport layer 18 may be made of, e.g., aluminum (8-hydroxy)quinolinate.

The organic EL layer 30 may further include layers other than the hole transport layer 14 and electron transport layer 18, e.g., a hole injection layer and an electron injection layer.

The optical property adjusting layer 24 may be made of an organic material transparent in the visible light region, which is the same as the material used in making the electron transport layer 18 or the hole transport layer 14. In other words, the optical property adjusting layer 24 may be formed of an electron-transporting-material layer or a hole-transporting-material layer.

The optical property adjusting layer 24 may have a refractive index equal to or greater than the refractive index of the organic EL layer 30. An inorganic compound such as SiO₂ or SiN may be contained in the optical property adjusting layer 24. A metallic compound such as ZnS, ZnO, TiO₂, ITO, IZO or ALO may be alternatively contained in the optical property adjusting layer 24.

The property separation layer 22 may be formed of an electric charge generation layer or a transparent electrode layer. In this regard, it is possible to use, e.g., HAT-CN, as the electric charge generation layer. As a transparent electrode layer, it is possible to use, e.g., a translucent conductive thin film layer made of a metal oxide such as ITO or IZO, or a metal such as Al, Ag, Cs, Li, Ca, Mg, or Zn.

The optical property adjusting layer 24 may contain a hole-transporting-material layer or an electron-transporting-material layer.

The property separation layer 22 may be formed of an electric charge generation layer, a transparent electrode layer, or a conductive thin film layer.

The optical property adjusting layer 24 may be transparent in the visible light region and have a light scattering property.

If a hole-transporting-material layer is used as the optical property adjusting layer 24, the property separation layer 22 may be an electric charge generation layer.

Alternatively, if an electron-transporting-material layer is used as the optical property adjusting layer 24, the property separation layer 22 may be a transparent electrode layer or a conductive thin film layer.

In the organic EL device 2 according to the first embodiment, the optical property adjusting layer 24 may be doped with a metal. As the doped metal, it is possible to use, e.g., Al, Ag, Mg, Ca, Li, Cs, Ni, Pd, Pt, Zn, or Au.

In the organic EL device 2 according to the first embodiment, the optical property adjusting layer 24 may also be doped with a material capable of forming a charge-transfer complex. As the charge-transfer complex, it is possible to use, e.g., a tetrathiafulvalene-tetracy anoquinodimethane (TTF-TCNQ) complex.

In the case where the property separation layer 22 is formed of an electric charge generation layer, the electric charge generation layer has a thickness of, e.g., about 0.1 nm to 100 nm The LUMO (Lowest Unoccupied Molecular Orbital) of the electric charge generation layer may be equal to or greater than 4.0 eV as an absolute value.

In addition, the HOMO (Highest Occupied Molecular Orbital) of the optical property adjusting layer 24 may be equal to or less than 6.0 eV as an absolute value.

Further, the energy level difference between the HOMO of the optical property adjusting layer 24 and the LUMO of the electric charge generation layer may be equal to or less than 1 eV.

The second electrode layer 20 may be formed of, e.g., a metal film having high reflectance, such as an Al film or an Ag film. In the case of a top and bottom emission configuration, to be described later, the second electrode layer 20 is formed of the same transparent electrode layer as the first electrode layer 12.

As shown in FIG. 1, the organic EL device 2 according to the first embodiment has a bottom emission configuration in which the substrate 10 is formed of a transparent substrate having a light emitting surface and the second electrode layer 20 is formed of a metal layer.

Alternatively, the organic EL device 2 according to the first embodiment may have a top emission and bottom emission configuration in which the substrate 10 is formed of a transparent substrate and the first electrode layer 12 and second electrode layer 20 are formed of a transparent electrode layer.

In addition, the organic EL device 2 according to the first embodiment may have a top emission configuration. In this configuration, the substrate 10, the first electrode layer 12, and the second electrode layer 20 are formed of an opaque substrate, a metal layer, and a transparent electrode layer, respectively. In this case, the substrate 10 may be formed of, e.g., a silicon substrate or a stainless steel substrate. The first electrode layer 12 may be formed of, e.g., an aluminum deposition film. The second electrode layer 20 may be formed of, e.g., ITO.

In the organic EL device 2 according to the first embodiment, the bulk refractive index of the material forming the optical property adjusting layer 24 in at least a portion of the wavelength region of 380 nm to 780 nm may be set to be greater than the refractive index of one of the substrate 10, the organic EL layer 30, the first electrode layer 12, or the second electrode layer 20. This configuration may also apply to the organic EL devices 2 according to the second through twenty-seventh embodiments, to be described later.

The organic EL device 2 according to the first embodiment includes the property separation layer 22, which makes it possible to keep constant the carrier injection balance and exciton generation efficiency within the organic EL layer 30 arranged below the property separation layer 22. In other words, the carrier injection balance and exciton generation efficiency may be optimized by adjusting the thickness of the respective layers within the organic EL layer 30 arranged below the property separation layer 22. As a result, it is possible to maximize the internal quantum efficiency.

The organic EL device 2 according to the first embodiment includes the optical property adjusting layer 24. By adjusting the properties and thickness of the optical property adjusting layer 24, it is possible to adjust the optical properties thereof and to enhance the light extraction efficiency. In other words, the optical interference may be optimized by adjusting the thickness of the optical property adjusting layer 24. As a result, it is possible to maximize the light extraction efficiency.

Thus, the internal quantum efficiency and the light extraction efficiency may be independently adjusted in the organic EL device 2 according to the first embodiment. It is therefore possible to readily maximize the final external quantum efficiency.

The organic EL device 2 according to the first embodiment includes the property separation layer 22 and the optical property adjusting layer 24. The optical properties may be independently adjusted by adjusting the properties and thickness of the optical property adjusting layer 24 while keeping constant the carrier injection balance and exciton generation efficiency within the organic EL layer 30 arranged below the property separation layer 22. Thus, it becomes easier to maximize the final external quantum efficiency.

With the first embodiment, it is possible to provide an organic EL device capable of simultaneously optimizing the internal quantum efficiency and the light extraction efficiency.

### Second Embodiment

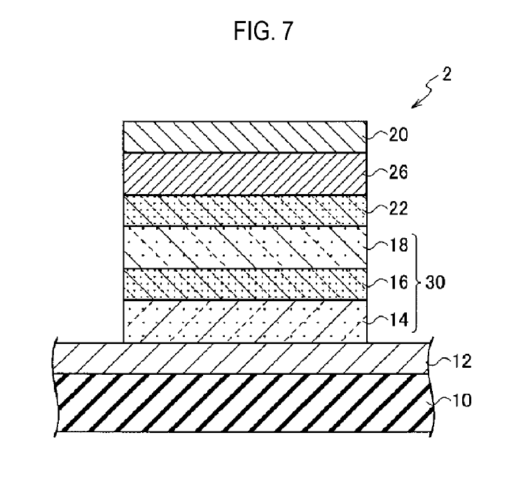

Referring to FIG. 7, an organic EL device 2 according to a second embodiment includes a polycrystalline organic material layer 26 as a substitute for the optical property adjusting layer 24 according to the first embodiment. The polycrystalline organic material layer 26 is transparent in the visible light region and has a light scattering property. Other configurations remain the same as those of the first embodiment, and no repeated description will be made on the same configurations.

With the second embodiment, the light usually confined within the organic EL layer 30 due to the total reflection may be extracted to the outside of the substrate through scattering in the polycrystalline organic material layer 26. It is therefore possible to further enhance the light extraction efficiency.

With the second embodiment, the light scattering property may be enhanced by employing the polycrystalline organic material layer 26. It is therefore possible to provide an organic EL device capable of simultaneously optimizing the internal quantum efficiency and the light extraction efficiency.

### Third Embodiment

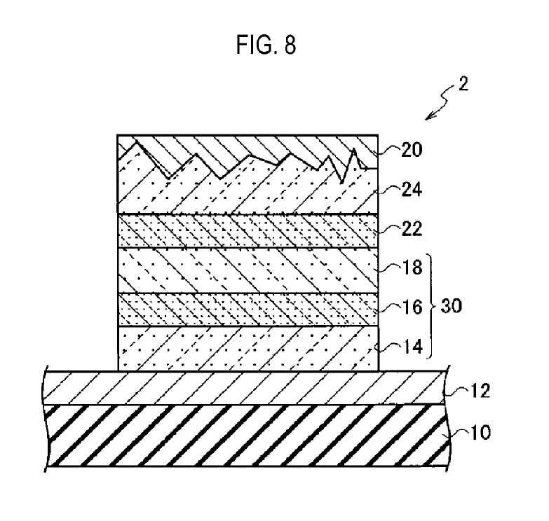

In the schematic cross-sectional structure of an organic EL device 2 according to a third embodiment shown in FIG. 8, the interface between the optical property adjusting layer 24 and the second electrode layer 20 has an uneven surface on which patterns are arranged randomly. The formation of the uneven surface, on which patterns are arranged randomly, in the interface between the optical property adjusting layer 24 and the second electrode layer 20 makes it possible to enhance a light scattering property while maintaining transparency in the visible light region. Other configurations remain the same as those of the first embodiment, and no repeated description will be made on the same configurations.

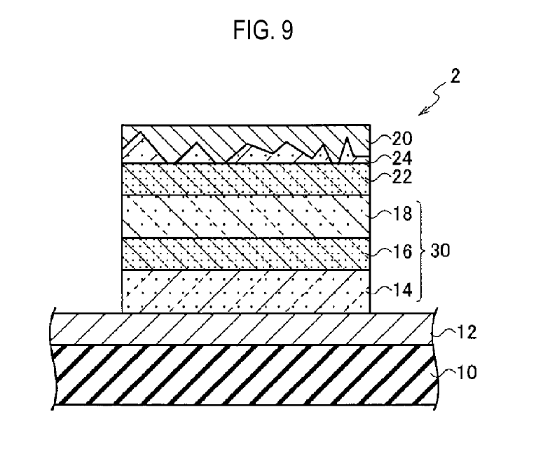

In the schematic cross-sectional structure of an organic EL device 2 according to a modified example of the third embodiment shown in FIG. 9, the interface between the optical property adjusting layer 24 and the second electrode layer 20 also has an uneven surface on which patterns are arranged randomly. The second electrode layer 20 is partially in contact with the property separation layer 22. The property separation layer 22 may be formed of an electric charge generation layer or a transparent electrode layer. Therefore, the property separation layer 22 may be partially short-circuited to the second electrode layer 20. Other configurations remain the same as those of the first embodiment, and no repeated description will be made on the same configurations.

With the modified example of the third embodiment, the short-circuit of the second electrode layer 20 and the property separation layer 22 makes it possible to directly inject carriers into the property separation layer 22 with no involvement of the optical property adjusting layer 24 when the carriers are injected from the side of the second electrode layer 20. It is therefore possible to suppress the drive voltage to remain low.

The formation conditions of the optical property adjusting layer 24 may be adjusted by using a poly-crystallizing material as the optical property adjusting layer 24. This makes it possible to increase the roughness Ra of the uneven surface on which patterns are arranged randomly.

With the third embodiment and the modified example thereof, the uneven surface on which patterns are arranged randomly is formed in the interface between the optical property adjusting layer 24 and the second electrode layer 20. This makes it possible to provide an organic EL device capable of enhancing a light scattering property and simultaneously optimizing the internal quantum efficiency and the light extraction efficiency.

### Fourth Embodiment

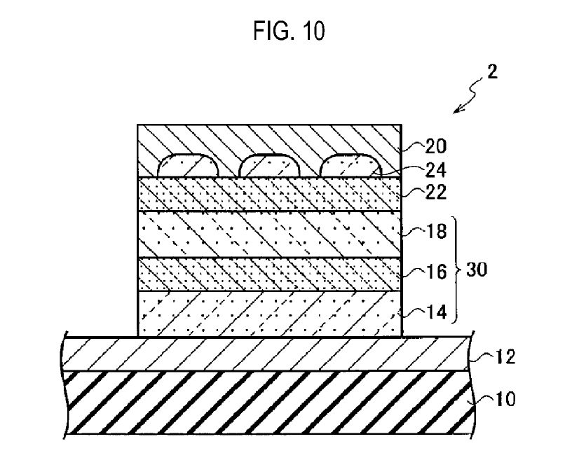

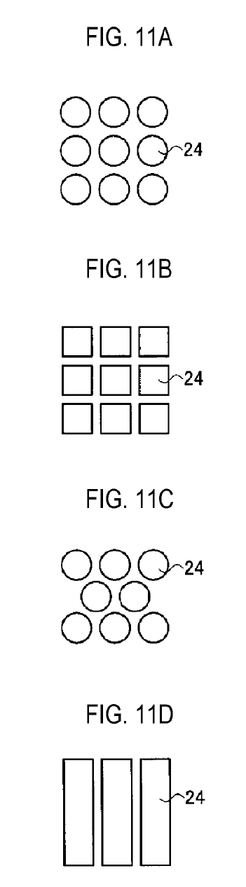

A schematic cross-sectional structure of an organic EL device 2 according to a fourth embodiment is shown in FIG. 10. FIGS. 11A through 11D are schematic plan pattern diagrams illustrating the optical property adjusting layer 24 in the organic EL device 2 according to the fourth embodiment. A circular pattern example is shown in FIG. 11A, a square pattern example is shown in FIG. 11B, a circular pattern example forming a triangle is shown in FIG. 11C, and a rectangular pattern example is shown in FIG. 11D.

In the organic EL device 2 according to the fourth embodiment shown in FIG. 10, the optical property adjusting layer 24 is patterned into a predetermined pattern structure and the second electrode layer 20 is partially in contact with the property separation layer 22. The pattern structure has one of a circular pattern, a square pattern, a circular pattern forming a triangle, and a rectangular pattern. Since the organic EL device 2 includes the optical property adjusting layer 24 patterned into a predetermined pattern structure, the interface between the optical property adjusting layer 24 and the second electrode layer 20 has an uneven surface on which patterns are arranged regularly. The second electrode layer 20 is partially in contact with the property separation layer 22. The property separation layer 22 may be formed of an electric charge generation layer or a transparent electrode layer. Therefore, the property separation layer 22 may be partially short-circuited to the second electrode layer 20. Other configurations remain the same as those of the first embodiment, and no repeated description will be made on the same configurations.

The step-height of the optical property adjusting layer 24 shown in FIG. 10 is, e.g., about 0.1 μm to 10 μm. The pitch of the patterns of the uneven surface is, e.g., about 0.1 μm to 500 μm.

The pattern structures of the optical property adjusting layer 24 shown in FIGS. 11A through 11D may be formed through the use of, e.g., a metal mask.

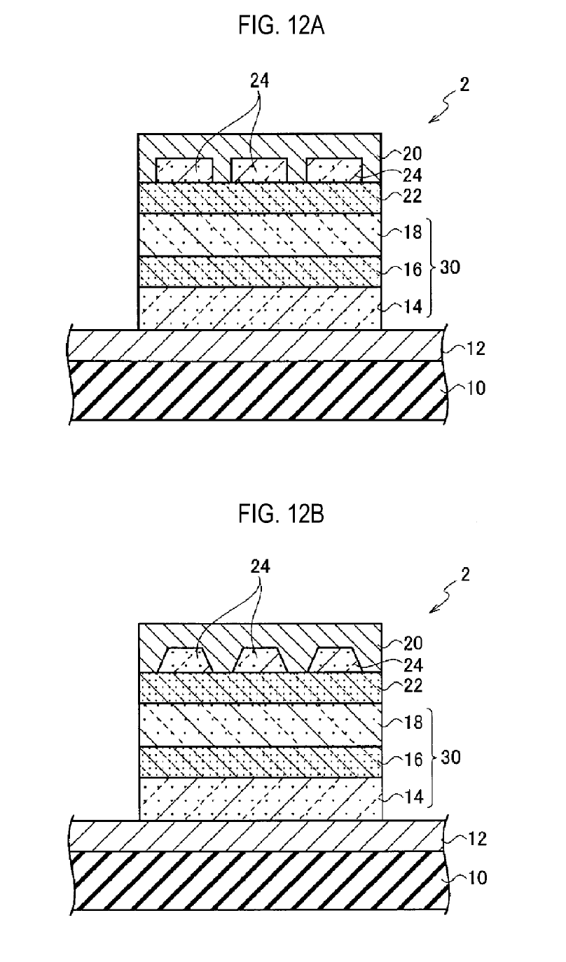

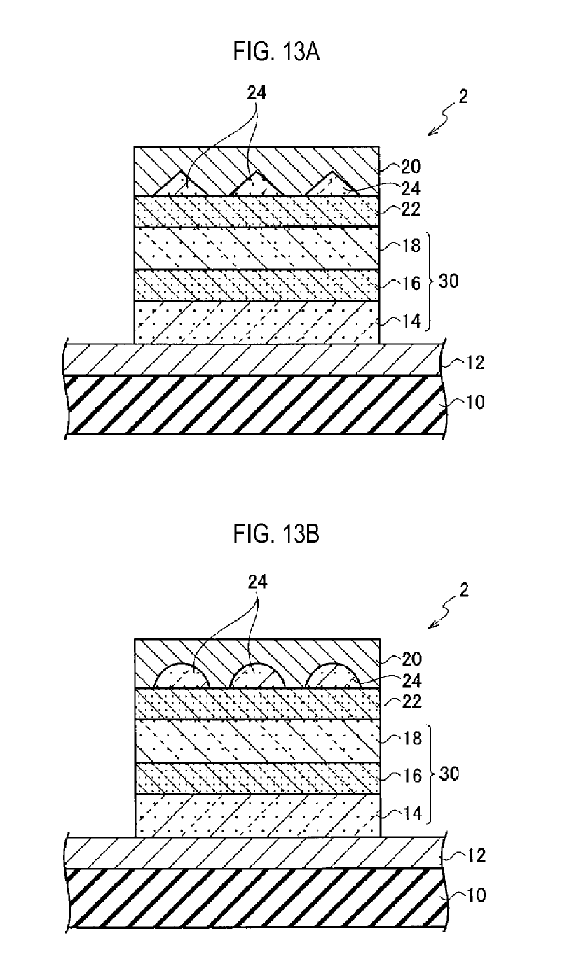

In an organic EL device 2 according to a first modified example of the fourth embodiment shown in FIG. 12A, the optical property adjusting layer 24 has a rectangular cross-sectional structure. In an organic EL device 2 according to a second modified example of the fourth embodiment shown in FIG. 12B, the optical property adjusting layer 24 has a trapezoidal cross-sectional structure. In an organic EL device 2 according to a third modified example of the fourth embodiment shown in FIG. 13A, the optical property adjusting layer 24 has a triangular cross-sectional structure. In an organic EL device 2 according to a fourth modified example of the fourth embodiment shown in FIG. 13B, the optical property adjusting layer 24 has a semicircular cross-sectional structure. Since each of the organic EL devices 2 according to the first through fourth modified examples includes the optical property adjusting layer 24 having a predetermined regular cross-sectional structure, the interface between the optical property adjusting layer 24 and the second electrode layer 20 has an uneven surface on which patterns are arranged regularly. The second electrode layer 20 is partially in contact with the property separation layer 22. The property separation layer 22 may be formed of an electric charge generation layer or a transparent electrode layer. Therefore, the property separation layer 22 may be partially short-circuited to the second electrode layer 20. Other configurations remain the same as those of the first embodiment, and no repeated description will be made on the same configurations.

As shown in FIG. 10, the organic EL device 2 according to the fourth embodiment includes the optical property adjusting layer 24 patterned into a predetermined pattern structure. Consequently, it is possible to impart an uneven shape to the second electrode layer 20. As a result, the light confined within the organic EL layer 30 or the substrate 10 is irregularly reflected and is escaped to the outside of the substrate 10. This makes it possible to enhance the external light emission efficiency.

With the fourth embodiment and the first through fourth modified examples thereof, the uneven surface on which patterns are arranged regularly is formed in the interface between the optical property adjusting layer 24 and the second electrode layer 20. This makes it possible to provide an organic EL device capable of enhancing a light scattering property and simultaneously optimizing the internal quantum efficiency and the light extraction efficiency.

### Fifth Embodiment

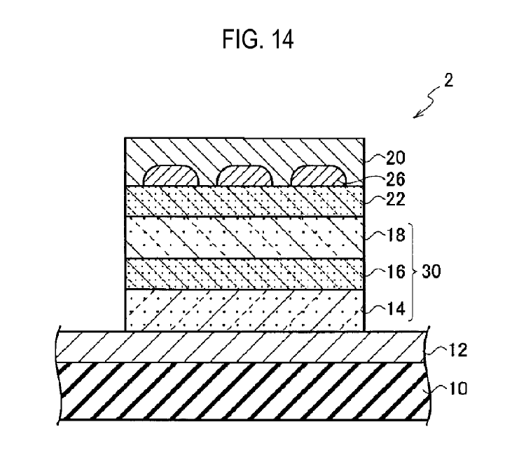

Referring to FIG. 14, an organic EL device 2 according to a fifth embodiment includes a patterned polycrystalline organic material layer 26 as a substitute for the optical property adjusting layer 24 employed in the fourth embodiment shown in FIG. 10. The polycrystalline organic material layer 26 is transparent in the visible light region and has a light scattering property. Other configurations remain the same as those of the fourth embodiment, and no repeated description will be made on the same configurations.

With the fifth embodiment, the use of the patterned polycrystalline organic material layer 26 makes it possible to provide an organic EL device capable of enhancing a light scattering property and simultaneously optimizing the internal quantum efficiency and the light extraction efficiency.

### Sixth Embodiment

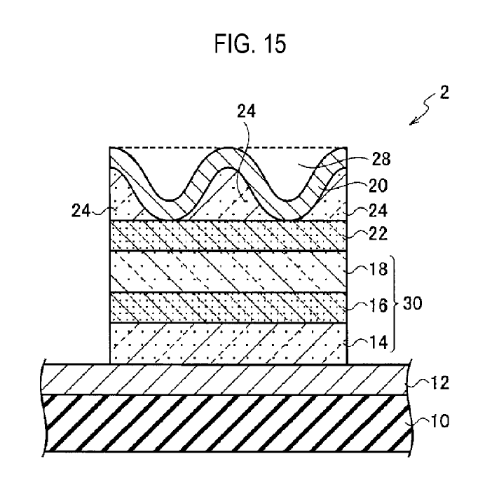

Referring to FIG. 15, an organic EL device 2 according to a sixth embodiment includes an optical property adjusting layer 24 having a wavy structure and a second electrode layer 20 having concave portions 28. The second electrode layer 20 is partially in contact with the property separation layer 22. The structure shown in FIG. 15 may be formed by using, as the optical property adjusting layer 24, an organic material having a glass transition point Tj lower than the glass transition point T of the organic EL layer 30. In other words, after formation of the second electrode layer 20, the optical property adjusting layer 24 may be softened by heating the optical property adjusting layer 24 to a temperature higher than the glass transition point Tj of the optical property adjusting layer 24 but lower than the glass transition point T of the organic EL layer 30. If a material having a high linear expansion coefficient is used as the second electrode layer 20, the second electrode layer 20 may be distorted by stresses. This makes it possible to form the structure shown in FIG. 15. The glass transition point (or glass temperature) T of the organic EL layer 30 is, e.g., about 80 degrees C.

While FIG. 15 illustrates an example in which the optical property adjusting layer 24 has a regular wavy structure, the present disclosure is not limited to this configuration. Alternatively, the interface between the optical property adjusting layer 24 and the second electrode layer 20 may be formed into an uneven structure in which patterns are arranged randomly.

With the sixth embodiment, the interface between the optical property adjusting layer 24 and the second electrode layer 20 has an uneven surface. It is therefore possible to provide an organic EL device capable of enhancing a light scattering property and simultaneously optimizing the internal quantum efficiency and the light extraction efficiency.

### Seventh Embodiment

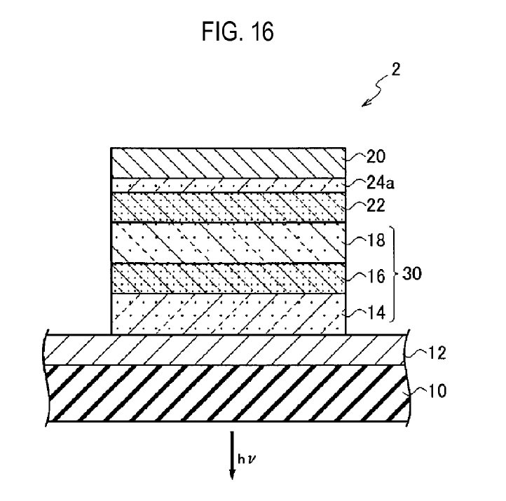

Referring to FIG. 16, an organic EL device 2 according to a seventh embodiment has a configuration in which an optical property adjusting layer 24a is made thinner than the optical property adjusting layer 24 of the first embodiment shown in FIG. 1. The thickness of the optical property adjusting layer 24a may be, e.g., 200 nm or less.

In the organic EL device 2 according to the seventh embodiment, the drive voltage may be reduced by thinning the optical property adjusting layer 24a.

### Eighth Embodiment

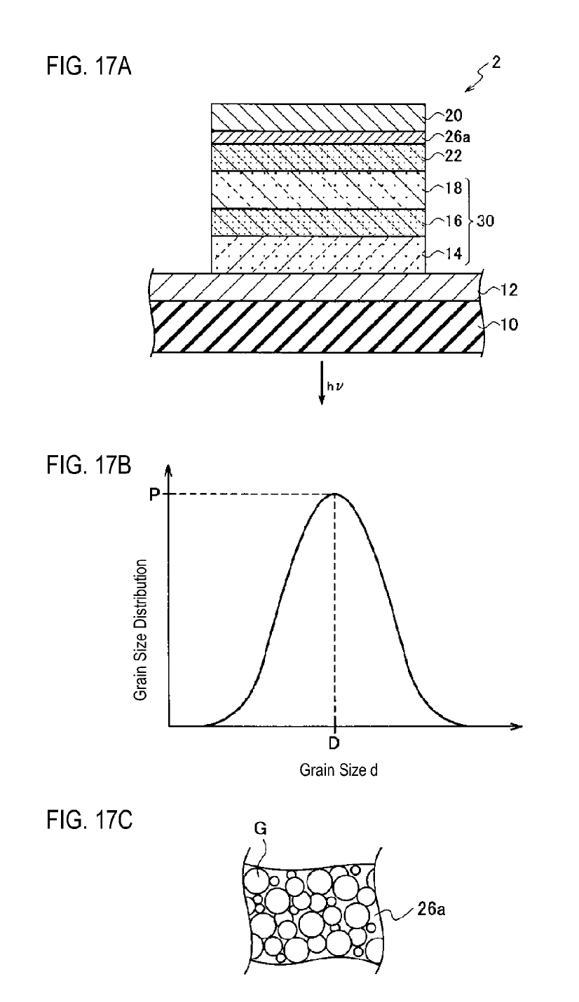

Referring to FIG. 17A, an organic EL device 2 according to an eighth embodiment has a configuration in which the optical property adjusting layer is formed of a polycrystalline organic material layer 26a and has a thickness substantially equal to or less than a grain size. The relationship between a grain size distribution and a grain size d is graphically shown in FIG. 17B. For example, the grain size distribution has a peak value P when the grain size d is equal to D. The shape of the grains G existing in the polycrystalline organic material layer 26a is schematically shown in FIG. 17C. The grain size d of the grains G is distributed in a range of, e.g., from D/10 to 10D.

In the organic EL device 2 according to the eighth embodiment, the optical property adjusting layer is formed of the polycrystalline organic material layer 26a and has a thickness substantially equal to or less than a grain size. This makes it possible to reduce the scattering effect with respect to the light moving toward the front side (the conventional outgoing light) and increase the scattering effect with respect to the light propagating substantially horizontally (in a thin film mode). In order to reduce the drive voltage, the thickness of the polycrystalline organic material layer 26a may be, e.g., 200 nm or less.

In the organic EL device 2 according to the eighth embodiment, the polycrystalline organic material layer 26a may be doped with a metal. As the doped metal, it is possible to use, e.g., Al, Ag, Mg, Ca, Li, Cs, Ni, Pd, Pt, Zn, or Au.

In the organic EL device 2 according to the eighth embodiment, the polycrystalline organic material layer 26a may also be doped with a material capable of forming a charge-transfer complex. As the charge-transfer complex, it is possible to use, e.g., a tetrathiafulvalene-tetracyanoquinodimethane (TTF-TCNQ) complex.

In the organic EL device 2 according to the eighth embodiment, it is possible to reduce the drive voltage because the polycrystalline organic material layer 26a is doped with a metal or a material capable of forming a charge-transfer complex.

### Ninth Embodiment

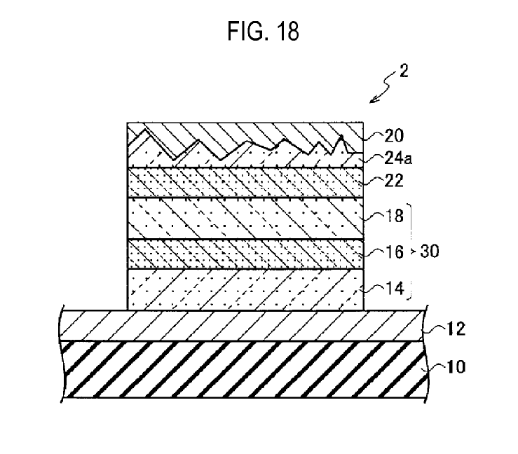

Referring to FIG. 18, an organic EL device 2 according to a ninth embodiment has a configuration in which an optical property adjusting layer 24a is made thinner than the optical property adjusting layer 24 of the third embodiment shown in FIG. 8. The thickness of the optical property adjusting layer 24a may be, e.g., 200 nm or less.

In the organic EL device 2 according to the ninth embodiment, the drive voltage may be reduced by thinning the optical property adjusting layer 24a.

### Tenth Embodiment

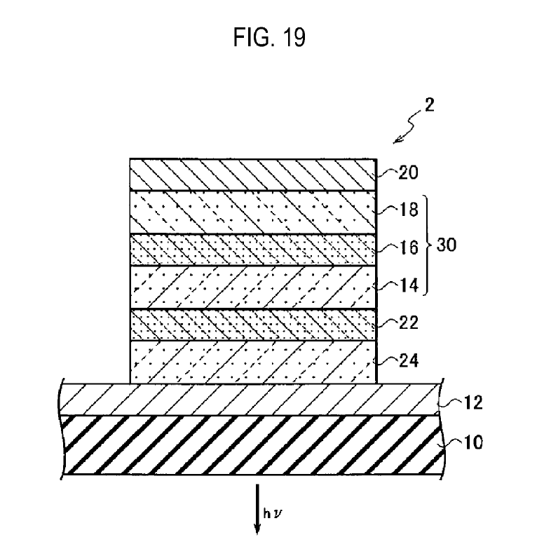

Referring to FIG. 19, an organic EL device 2 according to a tenth embodiment has a configuration in which the organic EL layer 30 of the first embodiment shown in FIG. 1 is arranged near the second electrode layer 20, and the optical property adjusting layer 24 and property separation layer 22 are disposed near the first electrode layer 12. In other words, the optical property adjusting layer 24 and the property separation layer 22 are arranged below the organic EL layer 30.

More specifically, as shown in FIG. 19, the organic EL device 2 according to the tenth embodiment includes a substrate 10, a first electrode layer 12 arranged on the substrate 10, an optical property adjusting layer 24 arranged on the first electrode layer 12, a property separation layer 22 arranged on the optical property adjusting layer 24, an organic EL layer 30 arranged on the property separation layer 22, and a second electrode layer 20 arranged on the organic EL layer 30. The organic EL layer 30 includes, e.g., a hole transport layer 14, a light emitting layer 16, and an electron transport layer 18, which are laminated one above another when viewed from the side of the substrate 10.

It is highly likely that the thin film mode light propagating through a thin film layer such as the optical property adjusting layer 24 exists largely within and around the first electrode layer 12 made of ITO, etc., and has a high refractive index.

In the organic EL device 2 according to the tenth embodiment, the optical property adjusting layer 24 functioning as a scattering layer is arranged adjacent to the first electrode layer 12 made of ITO, etc. This makes it possible to more easily extract the light to the outside and to enhance the light extraction efficiency.

In the organic EL device 2 according to the tenth embodiment, major electrodes may be selected from the second electrode layer 20 and the property separation layer 22. Alternatively, major electrodes may be selected from the second electrode layer 20 and the property separation layer 22 short-circuited to the first electrode layer 12. This electrode selection method may apply to the organic EL devices 2 according to the eleventh through twenty-seventh embodiments, to be described below.

### Eleventh Embodiment

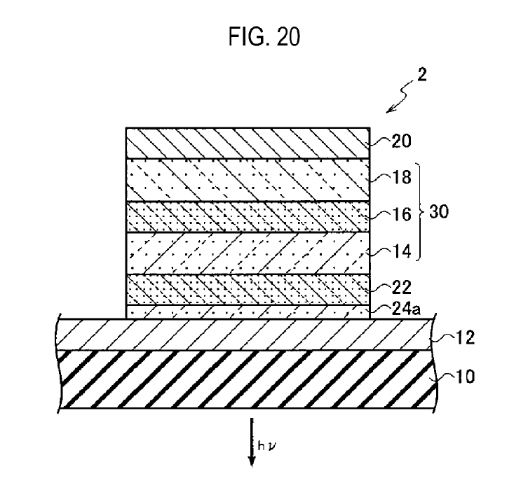

Referring to FIG. 20, an organic EL device 2 according to an eleventh embodiment has a configuration in which the optical property adjusting layer 24a is made thinner than the optical property adjusting layer 24 of the tenth embodiment shown in FIG. 19. The thickness of the optical property adjusting layer 24a may be, e.g., 200 nm or less.

In the organic EL device 2 according to the eleventh embodiment, the drive voltage may be reduced by thinning the optical property adjusting layer 24a.

### Twelfth Embodiment

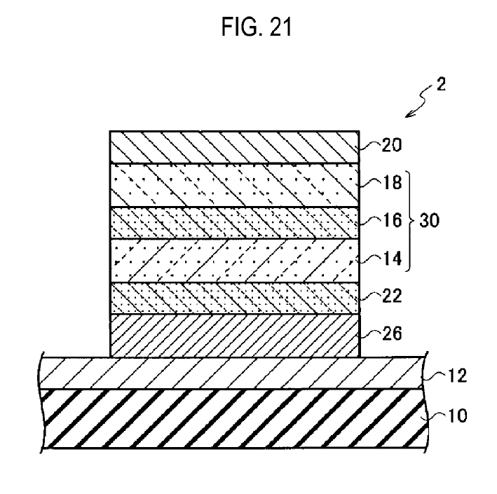

Referring to FIG. 21, an organic EL device 2 according to a twelfth embodiment has a configuration in which the organic EL layer 30 of the second embodiment shown in FIG. 7 is arranged near the second electrode layer 20, and the polycrystalline organic material layer 26 and the property separation layer 22 are disposed near the first electrode layer 12. In other words, the optical property adjusting layer is formed of the polycrystalline organic material layer 26. The polycrystalline organic material layer 26 and the property separation layer 22 are arranged below the organic EL layer 30.

More specifically, as shown in FIG. 21, the organic EL device 2 according to the twelfth embodiment includes a substrate 10, a first electrode layer 12 arranged on the substrate 10, a polycrystalline organic material layer 26 arranged on the first electrode layer 12, a property separation layer 22 arranged on the polycrystalline organic material layer 26, an organic EL layer 30 arranged on the property separation layer 22, and a second electrode layer 20 arranged on the organic EL layer 30. The organic EL layer 30 includes, e.g., a hole transport layer 14, a light emitting layer 16, and an electron transport layer 18, which are laminated one above another when viewed from the side of the substrate 10.

It is highly likely that the thin film mode light propagating through a thin film layer such as the polycrystalline organic material layer 26 exists largely within and around the first electrode layer 12 made of ITO, etc., and has a high refractive index.

In the organic EL device 2 according to the twelfth embodiment, the polycrystalline organic material layer 26 functioning as a scattering layer is arranged adjacent to the first electrode layer 12 made of ITO, etc. This makes it possible to more easily extract the light to the outside and to enhance the light extraction efficiency.

### Thirteenth Embodiment

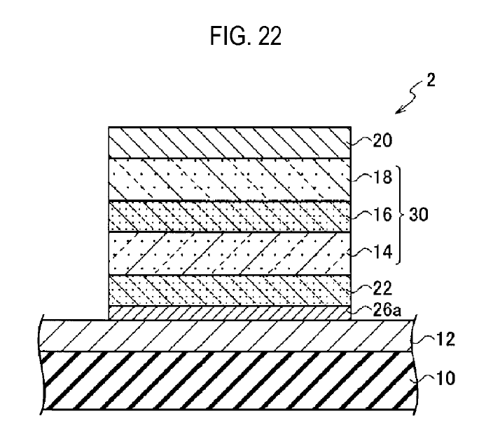

Referring to FIG. 22, an organic EL device 2 according to a thirteenth embodiment has a configuration in which the optical property adjusting layer is formed of a polycrystalline organic material layer 26a and has a thickness substantially equal to or less than a grain size. The relationship between a grain size distribution and a grain size d is graphically shown in FIG. 17B. For example, the grain size distribution has a peak value P when the grain size d is equal to D. The shape of the grains G existing in the polycrystalline organic material layer 26a is schematically shown in FIG. 17C. The grain size d of the grains G is distributed in a range of, e.g., from D/10 to 10D.

In the organic EL device 2 according to the thirteenth embodiment, the optical property adjusting layer is formed of the polycrystalline organic material layer 26a and has a thickness substantially equal to or less than a grain size. This makes it possible to reduce the scattering effect with respect to the light moving toward the front side (the conventional outgoing light) and increase the scattering effect with respect to the light propagating substantially horizontally (in a thin film mode). In order to reduce the drive voltage, the thickness of the polycrystalline organic material layer 26a may be, e.g., 200 nm or less.

In the organic EL device 2 according to the thirteenth embodiment, the polycrystalline organic material layer 26a may be doped with a metal. As the doped metal, it is possible to use, e.g., Al, Ag, Mg, Ca, Li, Cs, Ni, Pd, Pt, Zn, or Au.

In the organic EL device 2 according to the thirteenth embodiment, the polycrystalline organic material layer 26a may also be doped with a material capable of forming a charge-transfer complex. As the charge-transfer complex, it is possible to use, e.g., a tetrathiafulvalene-tetracyanoquinodimethane (TTF-TCNQ) complex.

In the organic EL device 2 according to the thirteenth embodiment, it is possible to further reduce the drive voltage because the polycrystalline organic material layer 26a is doped with a metal or a material capable of forming a charge-transfer complex.

In the organic EL device 2 according to the thirteenth embodiment, the polycrystalline organic material layer 26a functioning as a scattering layer is arranged adjacent to the first electrode layer 12 made of ITO etc. Thus, this makes it possible to more easily extract the light to the outside and to enhance the light extraction efficiency.

### Fourteenth Embodiment

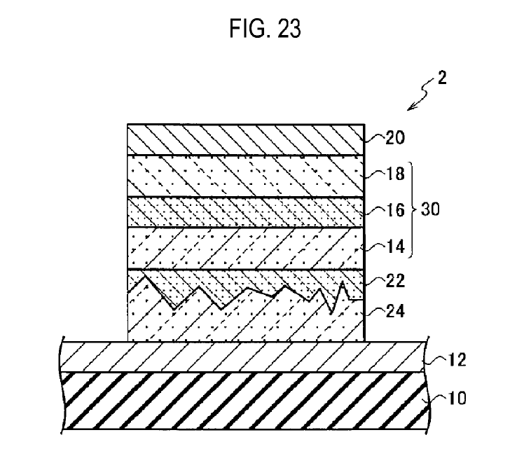

Referring to FIG. 23, an organic EL device 2 according to a fourteenth embodiment has a configuration in which the organic EL layer 30 of the third embodiment shown in FIG. 8 is disposed near the second electrode layer 20, and the optical property adjusting layer 24 and the property separation layer 22 are arranged near the first electrode layer 12. In other words, the optical property adjusting layer 24 and the property separation layer 22 are arranged below the organic EL layer 30.

More specifically, as shown in FIG. 23, the organic EL device 2 according to the fourteenth embodiment includes a substrate 10, a first electrode layer 12 arranged on the substrate 10, an optical property adjusting layer 24 arranged on the first electrode layer 12, a property separation layer 22 arranged on the optical property adjusting layer 24, an organic EL layer 30 arranged on the property separation layer 22, and a second electrode layer 20 arranged on the organic EL layer 30. The organic EL layer 30 includes, e.g., a hole transport layer 14, a light emitting layer 16, and an electron transport layer 18, which are laminated one above another when viewed from the side of the substrate 10.

In the schematic cross-sectional structure of the organic EL device 2 according to the fourteenth embodiment, as shown in FIG. 23, the interface between the optical property adjusting layer 24 and the property separation layer 22 has an uneven surface on which patterns are arranged randomly. Due to the uneven surface on which patterns are arranged randomly in the interface between the optical property adjusting layer 24 and the property separation layer 22, it is possible to enhance a light scattering property while maintaining transparency in the visible light region.

Although not shown in FIG. 23, the organic EL device 2 according to the fourteenth embodiment may have an uneven surface, on which patterns are arranged randomly, disposed in the interface between the optical property adjusting layer 24 and the first electrode layer 12.

The formation conditions of the optical property adjusting layer 24 may be adjusted by using a poly-crystallizing material as the optical property adjusting layer 24. Thus, this makes it possible to increase the roughness Ra of the uneven surface on which patterns are arranged randomly.

With the fourteenth embodiment, the uneven surface on which patterns are arranged randomly is formed in the interface between the optical property adjusting layer 24 and the property separation layer 20. This makes it possible to provide an organic EL device capable of enhancing a light scattering property and simultaneously optimizing the internal quantum efficiency and the light extraction efficiency.

It is highly likely that the thin film mode light propagating through a thin film layer such as the optical property adjusting layer 24 exists largely within and around the first electrode layer 12 made of ITO, etc., and has a high refractive index.

In the organic EL device 2 according to the fourteenth embodiment, the optical property adjusting layer 24 functioning as a scattering layer is arranged adjacent to the first electrode layer 12 made of ITO, etc. This makes it possible to more easily extract the light to the outside and to enhance the light extraction efficiency.

### Fifteenth Embodiment

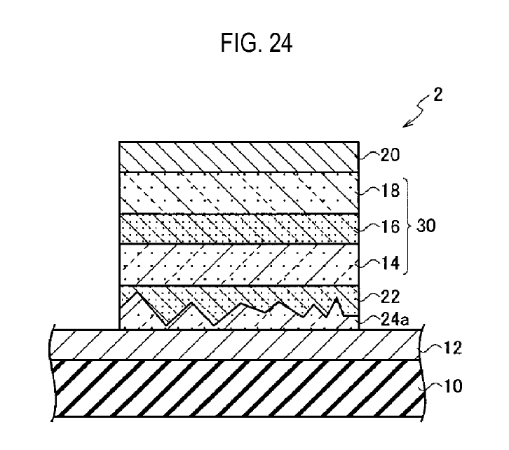

Referring to FIG. 24, an organic EL device 2 according to a fifteenth embodiment has a configuration in which an optical property adjusting layer 24a is made thinner than the optical property adjusting layer 24 of the fourteenth embodiment shown in FIG. 23. The thickness of the optical property adjusting layer 24a may be, e.g., 200 nm or less.

In the organic EL device 2 according to the fifteenth embodiment, the drive voltage may be reduced by thinning the optical property adjusting layer 24a.

### Sixteenth Embodiment

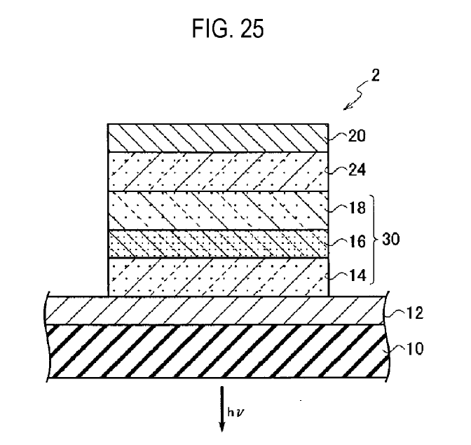

Referring to FIG. 25, an organic EL device 2 according to a sixteenth embodiment has a configuration in which the property separation layer 22 is omitted from the first embodiment shown in FIG. 1. In other words, as shown in FIG. 25, the organic EL device 2 according to the sixteenth embodiment includes a substrate 10, a first electrode layer 12 arranged on the substrate 10, an organic EL layer 30 arranged on the first electrode layer 12, an optical property adjusting layer 24 arranged on the organic EL layer 30, and a second electrode layer 20 arranged on the optical property adjusting layer 24. The optical property adjusting layer 24 is formed of an electron transport layer.

In the organic EL device 2 according to the sixteenth embodiment, it is possible to reduce the drive voltage and material cost by omitting the property separation layer 22.

### Seventeenth Embodiment

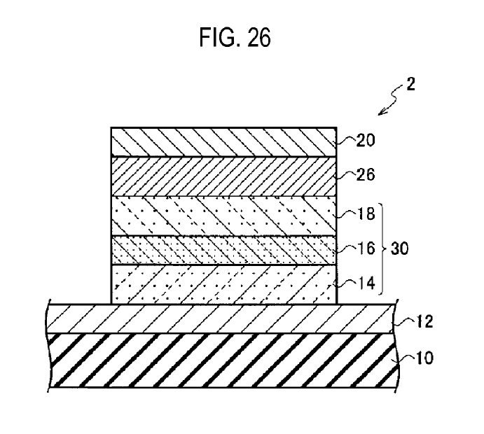

Referring to FIG. 26, an organic EL device 2 according to a seventeenth embodiment has a configuration in which the property separation layer 22 is omitted from the second embodiment shown in FIG. 7. In other words, as shown in FIG. 26, the organic EL device 2 according to the seventeenth embodiment includes a substrate 10, a first electrode layer 12 arranged on the substrate 10, an organic EL layer 30 arranged on the first electrode layer 12, a polycrystalline organic material layer 26 arranged on the organic EL layer 30, and a second electrode layer 20 arranged on the polycrystalline organic material layer 26. The polycrystalline organic material layer 26 is formed of an electron transport layer.

In the organic EL device 2 according to the seventeenth embodiment, it is possible to reduce the drive voltage and material cost by omitting the property separation layer 22.

### Eighteenth Embodiment

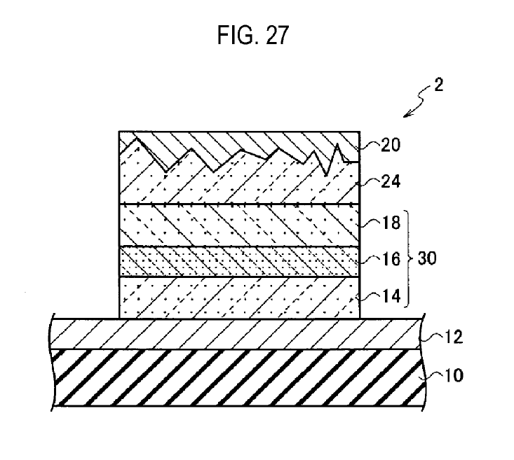

Referring to FIG. 27, an organic EL device 2 according to an eighteenth embodiment has a configuration in which the property separation layer 22 is omitted from the third embodiment shown in FIG. 8. In other words, as shown in FIG. 27, the organic EL device 2 according to the eighteenth embodiment includes a substrate 10, a first electrode layer 12 arranged on the substrate 10, an organic EL layer 30 arranged on the first electrode layer 12, an optical property adjusting layer 24 arranged on the organic EL layer 30, and a second electrode layer 20 arranged on the optical property adjusting layer 24. The optical property adjusting layer 24 is formed of an electron transport layer.

As shown in FIG. 27, the organic EL device 2 according to the eighteenth embodiment has an uneven surface, on which patterns are arranged randomly, disposed in the interface between the optical property adjusting layer 24 and the second electrode layer 20. Due to the uneven surface on which patterns are arranged randomly in the interface between the optical property adjusting layer 24 and the second electrode layer 20, it is possible to enhance a light scattering property while maintaining transparency in the visible light region.

The formation conditions of the optical property adjusting layer 24 may be adjusted by using a poly-crystallizing material as the optical property adjusting layer 24. Thus, this makes it possible to increase the roughness Ra of the uneven surface on which patterns are arranged randomly.

With the eighteenth embodiment, the uneven surface on which patterns are arranged randomly is formed in the interface between the optical property adjusting layer 24 and the second electrode layer 20. Thus, this makes it possible to provide an organic EL device capable of enhancing a light scattering property and simultaneously optimizing the internal quantum efficiency and the light extraction efficiency.

In the organic EL device 2 according to the eighteenth embodiment, it is possible to reduce the drive voltage and material cost by omitting the property separation layer 22.

### Nineteenth Embodiment

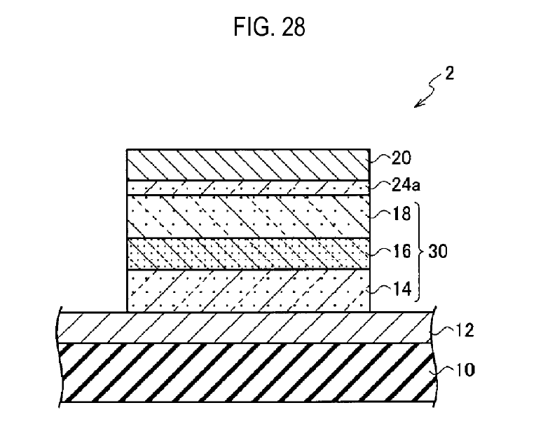

Referring to FIG. 28, an organic EL device 2 according to a nineteenth embodiment has a configuration in which the property separation layer 22 is omitted from the seventh embodiment shown in FIG. 16. In other words, as shown in FIG. 28, the organic EL device 2 according to the nineteenth embodiment includes a substrate 10, a first electrode layer 12 arranged on the substrate 10, an organic EL layer 30 arranged on the first electrode layer 12, an optical property adjusting layer 24a arranged on the organic EL layer 30, and a second electrode layer 20 arranged on the optical property adjusting layer 24a. The optical property adjusting layer 24a is formed of an electron transport layer.

As shown in FIG. 28, the organic EL device 2 according to the nineteenth embodiment has a configuration in which the optical property adjusting layer 24a is made thinner than the optical property adjusting layer 24 of the sixteenth embodiment shown in FIG. 25. The thickness of the optical property adjusting layer 24a may be, e.g., 200 nm or less.

In the organic EL device 2 according to the nineteenth embodiment, the drive voltage may be reduced by thinning the optical property adjusting layer 24a.

In the organic EL device 2 according to the nineteenth embodiment, it is possible to reduce the drive voltage and material cost by omitting the property separation layer 22.

### Twentieth Embodiment

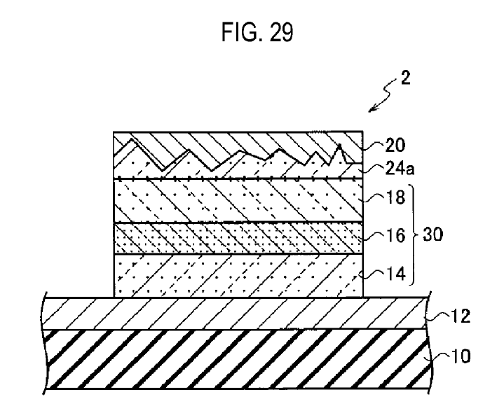

Referring to FIG. 29, an organic EL device 2 according to a twentieth embodiment has a configuration in which the property separation layer 22 is omitted from the ninth embodiment shown in FIG. 18. In other words, as shown in FIG. 29, the organic EL device 2 according to the twentieth embodiment includes a substrate 10, a first electrode layer 12 arranged on the substrate 10, an organic EL layer 30 arranged on the first electrode layer 12, an optical property adjusting layer 24a arranged on the organic EL layer 30, and a second electrode layer 20 arranged on the optical property adjusting layer 24a. The optical property adjusting layer 24a is formed of an electron transport layer.

As shown in FIG. 29, the organic EL device 2 according to the twentieth embodiment has a configuration in which the optical property adjusting layer 24a is made thinner than the optical property adjusting layer 24 of the sixteenth embodiment shown in FIG. 25. The thickness of the optical property adjusting layer 24a may be, e.g., 200 nm or less.

In the organic EL device 2 according to the twentieth embodiment, the drive voltage may be reduced by thinning the optical property adjusting layer 24a.

Further, in the organic EL device 2 according to the twentieth embodiment, it is possible to reduce the drive voltage and material cost by omitting the property separation layer 22.

In the schematic cross-sectional structure of the organic EL device 2 according to the twentieth embodiment, as shown in FIG. 29, the interface between the optical property adjusting layer 24a and the second electrode layer 20 has an uneven surface on which patterns are arranged randomly. Due to the uneven surface on which patterns are arranged randomly in the interface between the optical property adjusting layer 24a and the second electrode layer 20, it is possible to enhance a light scattering property while maintaining transparency in the visible light region.

The formation conditions of the optical property adjusting layer 24a may be adjusted by using a poly-crystallizing material as the optical property adjusting layer 24a. Thus, this makes it possible to increase the roughness Ra of the uneven surface on which patterns are arranged randomly.

With the twentieth embodiment, the uneven surface on which patterns are arranged randomly is formed in the interface between the optical property adjusting layer and the second electrode layer 20. This makes it possible to provide an organic EL device capable of enhancing a light scattering property and simultaneously optimizing the internal quantum efficiency and the light extraction efficiency.

### Twenty-First Embodiment

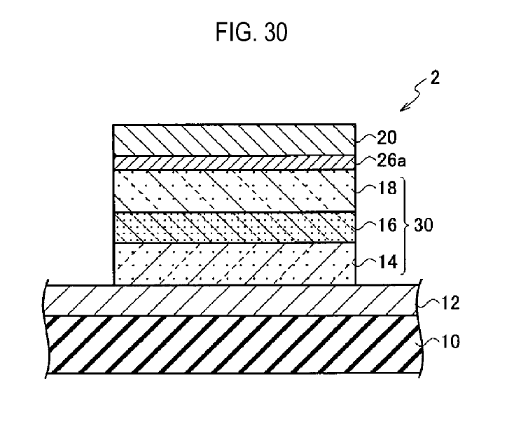

Referring to FIG. 30, an organic EL device 2 according to a twenty-first embodiment has a configuration in which the property separation layer 22 is omitted from the eighth embodiment shown in FIGS. 17A, 17B and 17C. In other words, as shown in FIG. 30, the organic EL device 2 according to the twenty-first embodiment includes a substrate 10, a first electrode layer 12 arranged on the substrate 10, an organic EL layer 30 arranged on the first electrode layer 12, a polycrystalline organic material layer 26a arranged on the organic EL layer 30, and a second electrode layer 20 arranged on the polycrystalline organic material layer 26a. The polycrystalline organic material layer 26a is formed of an electron transport layer.

As shown in FIG. 30, the organic EL device 2 according to the twenty-first embodiment has a configuration in which the polycrystalline organic material layer 26a is made thinner than the polycrystalline organic material layer 26 of the seventeenth embodiment shown in FIG. 26.

Further, as shown in FIG. 30, the organic EL device 2 according to the twenty-first embodiment has a configuration in which the optical property adjusting layer is formed of the polycrystalline organic material layer 26a and has a thickness substantially equal to or less than a grain size. The relationship between a grain size distribution and a grain size d is graphically shown in FIG. 17B. For example, the grain size distribution has a peak value P when the grain size d is equal to D. The shape of the grains G existing in the polycrystalline organic material layer 26a is schematically shown in FIG. 17C. The grain size d of the grains G is distributed in a range of, e.g., from D/10 to 10D.

In the organic EL device 2 according to the twenty-first embodiment, the optical property adjusting layer is formed of the polycrystalline organic material layer 26a and has a thickness substantially equal to or less than a grain size. Thus, this makes it possible to reduce the scattering effect with respect to the light moving toward the front side (the conventional outgoing light) and to increase the scattering effect with respect to the light propagating substantially horizontally (in a thin film mode). In order to reduce the drive voltage, the thickness of the polycrystalline organic material layer 26a may be, e.g., 200 nm or less.

In the organic EL device 2 according to the twenty-first embodiment, the polycrystalline organic material layer 26a may be doped with a metal. As the doped metal, it is possible to use, e.g., Ni, Pd, Pt, Zn, or Au.

In the organic EL device 2 according to the twenty-first embodiment, the polycrystalline organic material layer 26a may also be doped with a material capable of forming a charge-transfer complex. As the charge-transfer complex, it is possible to use, e.g., a tetrathiafulvalene-tetracyanoquinodimethane (TTF-TCNQ) complex.

In the organic EL device 2 according to the twenty-first embodiment, it is possible to further reduce the drive voltage because the polycrystalline organic material layer 26a is doped with a metal or a material capable of forming a charge-transfer complex.

### Twenty-Second Embodiment

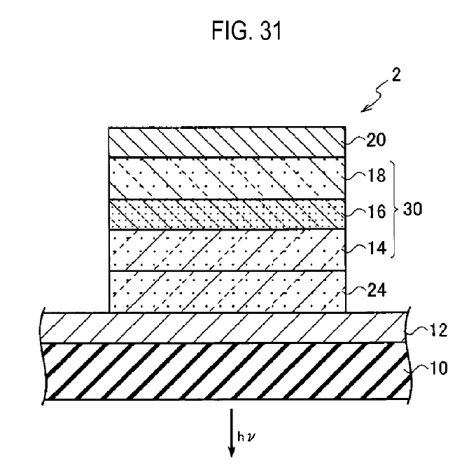

Referring to FIG. 31, an organic EL device 2 according to a twenty-second embodiment has a configuration in which the property separation layer 22 is omitted from the tenth embodiment shown in FIG. 19. In other words, as shown in FIG. 31, the organic EL device 2 according to the twenty-second embodiment has a configuration in which the organic EL layer 30 is arranged near the second electrode layer 20, and the optical property adjusting layer 24 is arranged near the first electrode layer 12. Thus, the optical property adjusting layer 24 is arranged below the organic EL layer 30.

More specifically, as shown in FIG. 31, the organic EL device 2 according to the twenty-second embodiment includes a substrate 10, a first electrode layer 12 arranged on the substrate 10, an optical property adjusting layer 24 arranged on the first electrode layer 12, an organic EL layer 30 arranged on the optical property adjusting layer 24, and a second electrode layer 20 arranged on the organic EL layer 30. The optical property adjusting layer 24 is formed of a hole transport layer. The organic EL layer 30 includes, e.g., a hole transport layer 14, a light emitting layer 16, and an electron transport layer 18, which are laminated one above another when viewed from the side of the substrate 10.

It is highly likely that the thin film mode light propagating through a thin film layer such as the optical property adjusting layer 24 exists largely within and around the first electrode layer 12 made of ITO, etc., and has a high refractive index.

In the organic EL device 2 according to the twenty-second embodiment, the optical property adjusting layer 24 functioning as a scattering layer is arranged adjacent to the first electrode layer 12 made of ITO, etc. This makes it possible to more easily extract the light to the outside and to enhance the light extraction efficiency. Further, in the organic EL device 2 according to the twenty-second embodiment, it is possible to reduce the drive voltage and material cost by omitting the property separation layer 22.

### Twenty-Third Embodiment

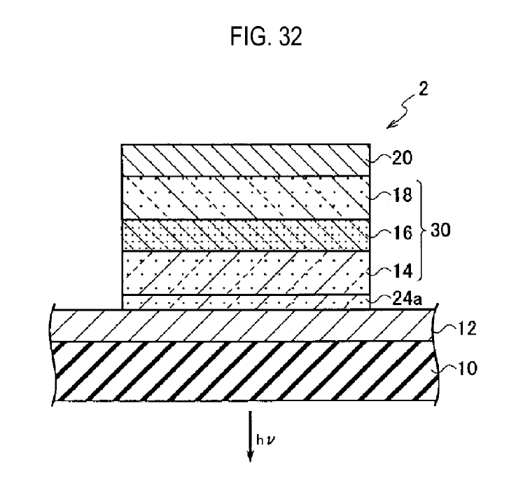

Referring to FIG. 32, an organic EL device 2 according to a twenty-third embodiment has a configuration in which an optical property adjusting layer 24a is made thinner than the optical property adjusting layer 24 of the twenty-second embodiment shown in FIG. 31. The thickness of the optical property adjusting layer 24a may be, e.g., 200 nm or less.

In the organic EL device 2 according to the twenty-third embodiment, the drive voltage may be reduced by thinning the optical property adjusting layer 24a.

### Twenty-Fourth Embodiment

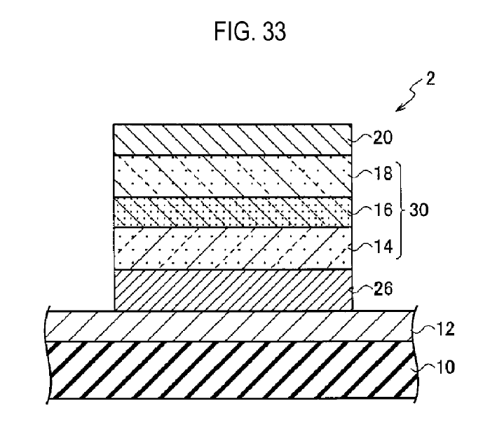

Referring to FIG. 33, an organic EL device 2 according to a twenty-fourth embodiment has a configuration in which the property separation layer 22 is omitted from the twelfth embodiment shown in FIG. 21. In other words, as shown in FIG. 33, the organic EL device 2 according to the twenty-fourth embodiment has a configuration in which the organic EL layer 30 is arranged near the second electrode layer 20, and the polycrystalline organic material layer 26 is arranged near the first electrode layer 12. Thus, the polycrystalline organic material layer 26 is arranged below the organic EL layer 30.

More specifically, as shown in FIG. 33, the organic EL device 2 according to the twenty-fourth embodiment includes a substrate 10, a first electrode layer 12 arranged on the substrate 10, a polycrystalline organic material layer 26 arranged on the first electrode layer 12, an organic EL layer 30 arranged on the polycrystalline organic material layer 26, and a second electrode layer 20 arranged on the organic EL layer 30. The polycrystalline organic material layer 26 is formed of a hole transport layer. The organic EL layer 30 includes, e.g., a hole transport layer 14, a light emitting layer 16, and an electron transport layer 18, which are laminated one above another when viewed from the side of the substrate 10.

It is highly likely that the thin film mode light propagating through a thin film layer such as the polycrystalline organic material layer 26 exists largely within and around the first electrode layer 12 made of ITO, etc., and has a high refractive index.

In the organic EL device 2 according to the twenty-fourth embodiment, the polycrystalline organic material layer 26 functioning as a scattering layer is arranged adjacent to the first electrode layer 12 made of ITO, etc. Thus, this makes it possible to more easily extract the light to the outside and to enhance the light extraction efficiency.

Further, in the organic EL device 2 according to the twenty-fourth embodiment, it is possible to reduce the drive voltage and material cost by omitting the property separation layer 22.

### Twenty-Fifth Embodiment

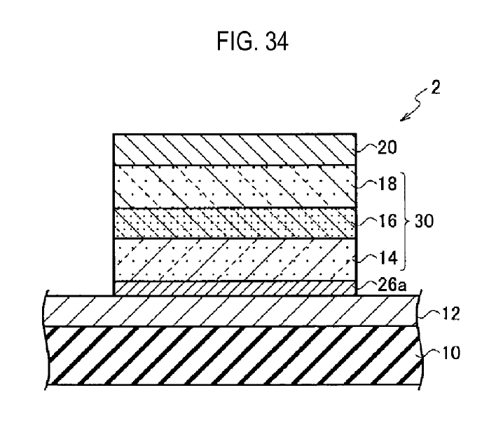

Referring to FIG. 34, an organic EL device 2 according to a twenty-fifth embodiment has a configuration in which the polycrystalline organic material layer 26a is made thinner than the polycrystalline organic material layer 26 of the twenty-fourth embodiment shown in FIG. 33.

As shown in FIG. 34, the organic EL device 2 according to the twenty-fifth embodiment has a configuration in which the optical property adjusting layer is formed of a polycrystalline organic material layer 26a and has a thickness substantially equal to or less than a grain size. The relationship between a grain size distribution and a grain size d is graphically shown in FIG. 17B. For example, the grain size distribution has a peak value P when the grain size d is equal to D. The shape of the grains G existing in the polycrystalline organic material layer 26a is schematically shown in FIG. 17C. The grain size d of the grains G is distributed in a range of, e.g., from D/10 to 10D.

In the organic EL device 2 according to the twenty-fifth embodiment, the optical property adjusting layer is formed of the polycrystalline organic material layer 26a and has a thickness substantially equal to or less than a grain size. This makes it possible to reduce the scattering effect with respect to the light moving toward the front side (the conventional outgoing light) and to increase the scattering effect with respect to the light propagating substantially horizontally (in a thin film mode). In order to reduce the drive voltage, the thickness of the polycrystalline organic material layer 26a may be, e.g., 200 nm or less.

In addition, in the organic EL device 2 according to the twenty-fifth embodiment, the polycrystalline organic material layer 26a may be doped with a metal. As the doped metal, it is possible to use, e.g., Ni, Pd, Pt, Zn, or Au.

In the organic EL device 2 according to the twenty-fifth embodiment, the polycrystalline organic material layer 26a may also be doped with a material capable of forming a charge-transfer complex. As the charge-transfer complex, it is possible to use, e.g., a tetrathiafulvalene-tetracyanoquinodimethane (TTF-TCNQ) complex.

In the organic EL device 2 according to the twenty-fifth embodiment, it is possible to further reduce the drive voltage because the polycrystalline organic material layer 26a is doped with a metal or a material capable of forming a charge-transfer complex.

Further, in the organic EL device 2 according to the twenty-fifth embodiment, the polycrystalline organic material layer 26a functioning as a scattering layer is arranged adjacent to the first electrode layer 12 made of ITO, etc. This makes it possible to more easily extract the light to the outside and to enhance the light extraction efficiency.

### Twenty-Sixth Embodiment

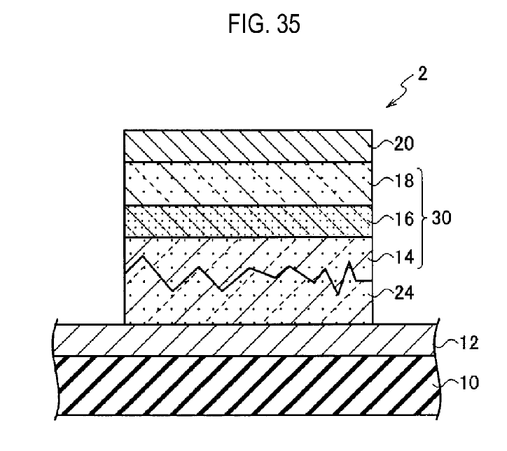

Referring to FIG. 35, an organic EL device 2 according to a twenty-sixth embodiment has a configuration in which the property separation layer 22 is omitted from the fourteenth embodiment shown in FIG. 23. In other words, as shown in FIG. 35, the organic EL device 2 according to the twenty-sixth embodiment has a configuration in which the organic EL layer 30 is arranged near the second electrode layer 20, and the optical property adjusting layer 24 is arranged near the first electrode layer 12. Thus, the optical property adjusting layer 24 is arranged below the organic EL layer 30.

More specifically, as shown in FIG. 35, the organic EL device 2 according to the twenty-sixth embodiment includes a substrate 10, a first electrode layer 12 arranged on the substrate 10, an optical property adjusting layer 24 arranged on the first electrode layer 12, an organic EL layer 30 arranged on the optical property adjusting layer 24, and a second electrode layer 20 arranged on the organic EL layer 30. The optical property adjusting layer 24 is formed of a hole transport layer. The organic EL layer 30 includes, e.g., a hole transport layer 14, a light emitting layer 16, and an electron transport layer 18, which are laminated one above another when viewed from the side of the substrate 10.

In the schematic cross-sectional structure of the organic EL device 2 according to the twenty-sixth embodiment, as shown in FIG. 35, the interface between the optical property adjusting layer 24 and the hole transport layer 14 has an uneven surface on which patterns are arranged randomly. Due to the uneven surface on which patterns are arranged randomly in the interface between the optical property adjusting layer 24 and the hole transport layer 14, it is possible to enhance a light scattering property while maintaining transparency in the visible light region.

While not shown in FIG. 35, the organic EL device 2 according to the twenty-sixth embodiment may have an uneven surface on which patterns are arranged randomly in the interface between the optical property adjusting layer 24 and the first electrode layer 12.

The formation conditions of the optical property adjusting layer 24 may be adjusted by using a poly-crystallizing material as the optical property adjusting layer 24. Thus, this makes it possible to increase the roughness Ra of the uneven surface on which patterns are arranged randomly.

With the twenty-sixth embodiment, the uneven surface on which patterns are arranged randomly is formed in the interface between the optical property adjusting layer and the hole transport layer. Thus, this makes it possible to provide an organic EL device capable of enhancing a light scattering property and simultaneously optimizing the internal quantum efficiency and the light extraction efficiency.

It is highly likely that the thin film mode light propagating through a thin film layer such as the optical property adjusting layer 24 exists largely within and around the first electrode layer 12 made of ITO, etc., and has a high refractive index.

In the organic EL device 2 according to the twenty-sixth embodiment, the optical property adjusting layer 24 functioning as a scattering layer is arranged adjacent to the first electrode layer 12 made of ITO, etc. Thus, this makes it possible to more easily extract the light to the outside and to enhance the light extraction efficiency.

### Twenty-Seventh Embodiment

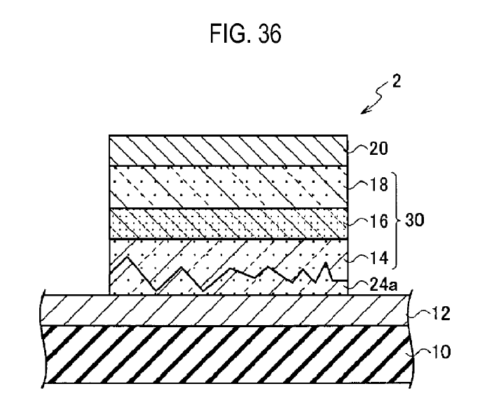

Referring to FIG. 36, an organic EL device 2 according to a twenty-seventh embodiment has a configuration in which an optical property adjusting layer 24a is made thinner than the optical property adjusting layer 24 of the twenty-sixth embodiment shown in FIG. 35. The thickness of the optical property adjusting layer 24a may be, e.g., 200 nm or less.

In the organic EL device 2 according to the twenty-seventh embodiment, the drive voltage may be reduced by thinning the optical property adjusting layer 24a.

### Twenty-Eighth Embodiment

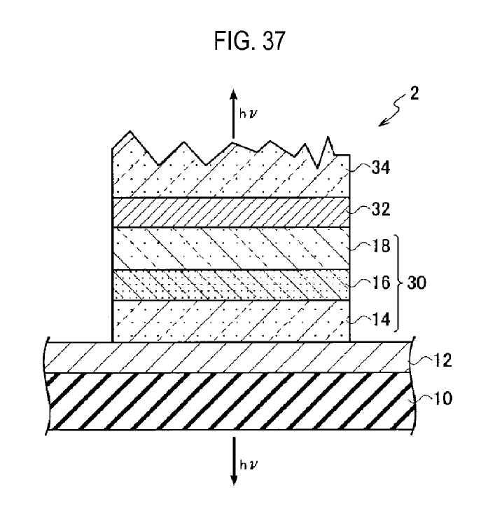

Referring to FIG. 37, an organic EL device 2 according to a twenty-eighth embodiment includes a transparent electrode (or second electrode layer) 32 as a substitute for the optical property adjusting layer 24 of the first embodiment shown in FIG. 1 and a high-refractive-index scattering layer 34 as a substitute for the second electrode layer (cathode electrode layer) 20 of the first embodiment shown in FIG. 1.

More specifically, as shown in FIG. 37, the organic EL device 2 according to the twenty-eighth embodiment includes a substrate 10, a first electrode layer 12 arranged on the substrate 10, an organic EL layer 30 arranged on the first electrode layer 12, a transparent electrode 32 arranged on the organic EL layer 30 and a high-refractive-index scattering layer 34 arranged on the transparent electrode 32.

The organic EL layer 30 includes, e.g., a hole transport layer 14, a light emitting layer 16, and an electron transport layer 18, which are laminated one above another when viewed from the side of the substrate 10. The laminating order of the respective layers of the organic EL layer 30 may be suitably changed. Further, it may be possible to use a mixed layer.

The transparent electrode 32 may be formed of a semiconductor oxide such as ITO or IZO, or a thin translucent film made of a metal such as a Mg—Ag alloy or Al. In addition, the transparent electrode 32 may be formed of a material other than those mentioned above as long as the material is transparent and electrically conductive.

The high-refractive-index scattering layer 34 may be formed of an organic material layer or a polycrystalline organic material layer which is transparent in the visible light region.

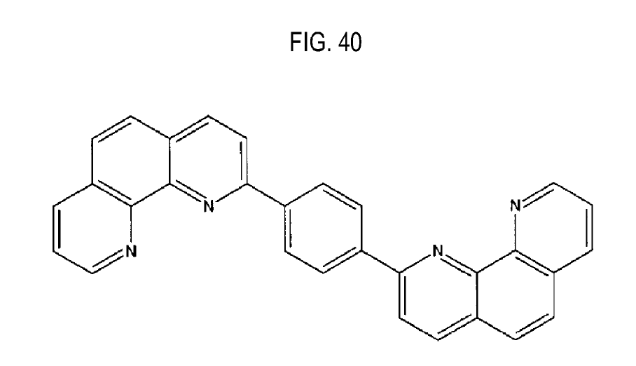

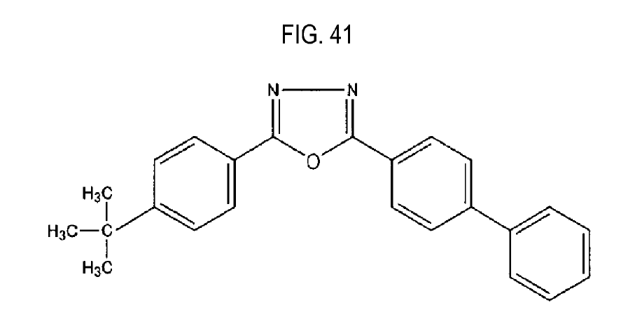

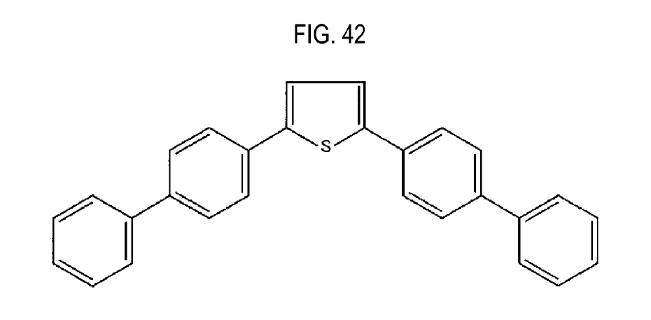

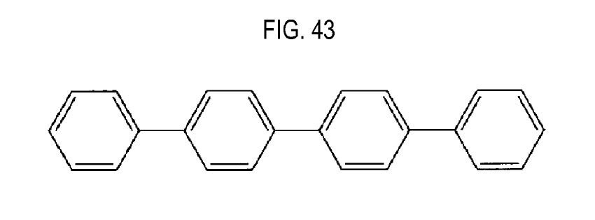

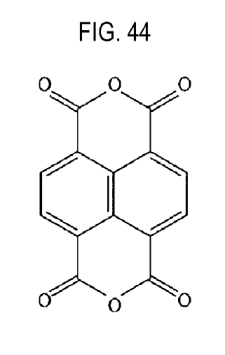

More specifically, the high-refractive-index scattering layer 34 may be made of 1,4-di(1,10-phenanthroline-2-yl) benzene (DPB), 2-(4-tert-butylphenyl)-5-(4-biphenyl)-1,3,4-oxadiazole (PBD), 2,5-bis(4-biphenylyl) thiophene (BP1T), p-quaterphenyl(p-4P), and naphthalene-1,4,5,8-tetracarboxylic dianhydride (NTDA), the chemical structural formulae of which are shown in FIGS. 40 through 44. For example, the LUMO level of PBD is about 2.4 eV and the HOMO level of PBD is about 5.9 eV. The energy difference between the HOMO level and the LUMO level is about 3.5 eV. The HOMO level of BP1T is about 5.1 eV. Further, the LUMO level of p-4P is about 2.0 eV and the HOMO level of p-4P is about 5.7 eV. The energy difference between the HOMO level and the LUMO level of p-4P is about 3.7 eV.

The thickness of the high-refractive-index scattering layer 34 may be about 10 nm to 10 μm (more specifically, about 10 nm to 1 μm). In particular, the thickness of the high-refractive-index scattering layer 34 may be 200 nm or less.

As shown in FIG. 37, the surface of the high-refractive-index scattering layer 34 includes an uneven surface on which patterns are arranged randomly. The formation conditions of the high-refractive-index scattering layer 34 may be adjusted by using a poly-crystallizing material as the high-refractive-index scattering layer 34. This makes it possible to increase the roughness Ra of the uneven surface on which patterns are arranged randomly. Thus, the light scattering property grows higher.

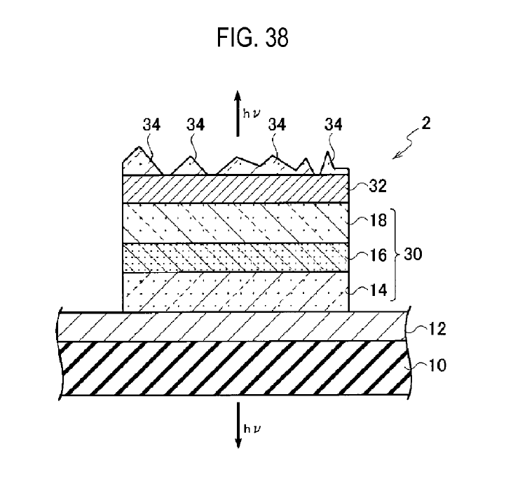

Further, in the schematic cross-sectional structure of an organic EL device 2 according to a first modified example of the twenty-eighth embodiment, as shown in FIG. 38, the high-refractive-index scattering layer 34 is formed into island-like shapes. Other configurations remain the same as those of the twenty-eighth embodiment, and no repeated description will be made on the same configurations.

The formation conditions of the high-refractive-index scattering layer 34 may be adjusted by using a poly-crystallizing material as the high-refractive-index scattering layer 34. Thus, this makes it possible to increase the roughness Ra of the uneven surface on which patterns are arranged randomly.

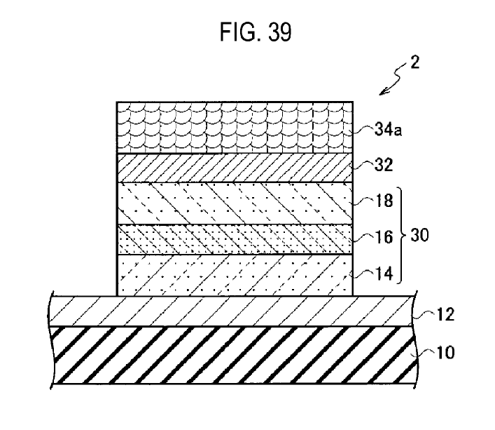

In the schematic cross-sectional structure of an organic EL device 2 according to a second modified example of the twenty-eighth embodiment, as shown in FIG. 39, a high-refractive-index scattering layer 34a having grain boundaries is arranged on the transparent electrode 32. This makes it possible to enhance a light scattering property without having to form unevenness on the surface of the high-refractive-index scattering layer 34a.

The high-refractive-index scattering layer 34 having grain boundaries may be formed of a polycrystalline organic material layer. The thickness of the polycrystalline organic material layer may be substantially equal to or less than a grain size.

Other configurations remain the same as those of the twenty-eighth embodiment, and no repeated description will be made on the same configurations.

In the organic EL devices 2 according to the twenty-eighth embodiment and the first and second modified examples thereof, the bulk refractive index of the material forming the high-refractive-index scattering layer 34 or 34a in at least a portion of the wavelength region of 380 nm to 780 nm may be set greater than the refractive index of one of the substrate 10, the organic EL layer 30, the first electrode layer 12, and the second electrode layer (transparent electrode) 32. This configuration may also apply to the organic EL devices 2 according to the twenty-ninth through thirty-fifth embodiments to be described later.

Further, in the organic EL devices 2 according to the twenty-eighth embodiment and the first and second modified examples thereof, the light (hν) is emitted from both the surface of the substrate 10 and the surface of the high-refractive-index scattering layer 34 or 34a.

With the organic EL devices 2 according to the twenty-eighth embodiment and the first and second modified examples thereof, it is possible to reduce or remove a surface plasmon loss by using the transparent electrode 32.

The provision of the high-refractive-index scattering layer 34 or 34a makes it possible to convert a thin film mode to a substrate mode or an external mode.

Accordingly, it is possible to extract the light with the quantity corresponding to the surface plasmon loss, which is higher in proportion than other losses, and the thin film wave guide mode loss. This makes it possible to greatly enhance the light extraction efficiency.

### Twenty-Ninth Embodiment

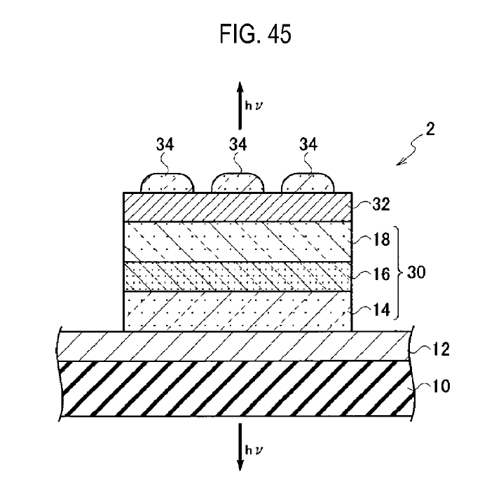

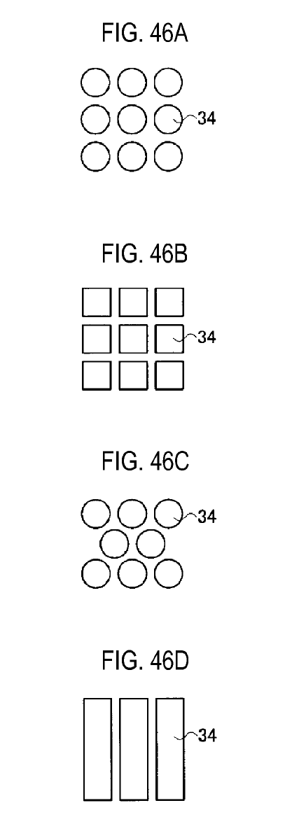

A schematic cross-sectional structure of an organic EL device 2 according to a twenty-ninth embodiment is shown in FIG. 45. FIGS. 46A through 46D are schematic plan pattern diagrams illustrating the high-refractive-index scattering layer 34 in the organic EL device 2 according to the twenty-ninth embodiment. A circular pattern example is shown in FIG. 46A, a square pattern example is shown in FIG. 46B, a circular pattern example forming a triangle is shown in FIG. 46C, and a rectangular pattern example is shown in FIG. 46D.

As shown in FIG. 45, the organic EL device 2 according to the twenty-ninth embodiment includes a high-refractive-index scattering layer 34 formed of a polycrystalline material patterned into a predetermined pattern structure, as a substitute for the high-refractive-index scattering layer 34 having an uneven surface, on which patterns are arranged randomly, employed in the twenty-eighth embodiment shown in FIG. 37.

The pattern structure is one of a circular pattern, square pattern, circular pattern forming a triangle, and rectangular pattern. Other configurations remain the same as those of the twenty-eighth embodiment, and no repeated description will be made on the same configurations.

The level difference of the high-refractive-index scattering layer 34 is about 10 nm to 10 μm (more specifically, about 100 nm to 1 μm).

The pattern structures of the high-refractive-index scattering layer 34 shown in FIGS. 46A through 46D may be formed through the use of, e.g., a metal mask.

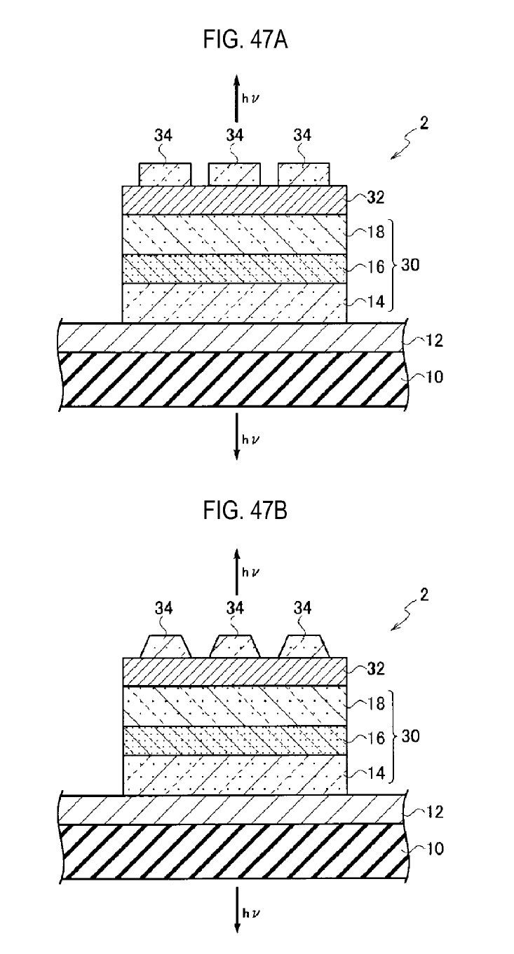

In an organic EL device 2 according to a first modified example of the twenty-ninth embodiment, as shown in FIG. 47A, the high-refractive-index scattering layer 34 has a rectangular cross-sectional structure. In an organic EL device 2 according to a second modified example of the twenty-ninth embodiment, as shown in FIG. 47B, the high-refractive-index scattering layer 34 has a trapezoidal cross-sectional structure.

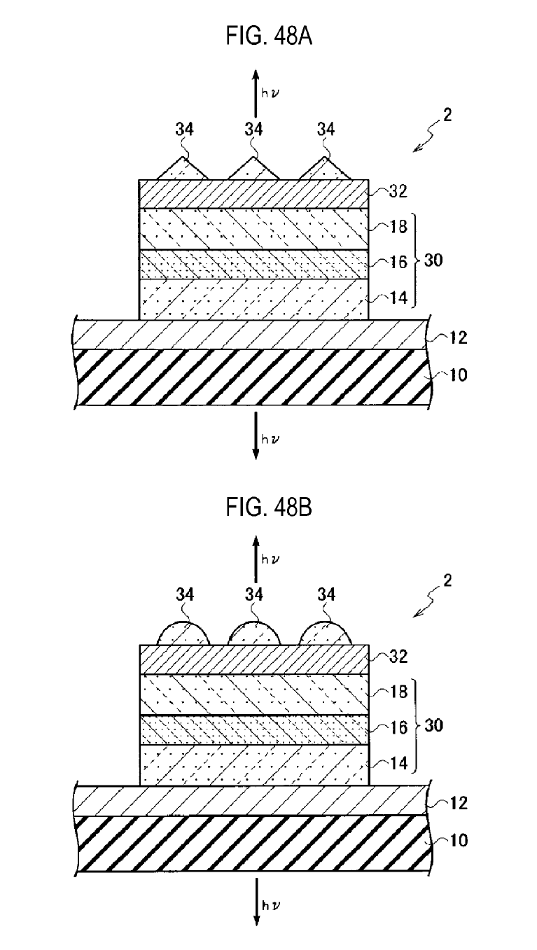

Further, in an organic EL device 2 according to a third modified example of the twenty-ninth embodiment, as shown in FIG. 48A, the high-refractive-index scattering layer 34 has a triangular cross-sectional structure. In an organic EL device 2 according to a fourth modified example of the twenty-ninth embodiment, as shown in FIG. 48B, the high-refractive-index scattering layer 34 has a semicircular cross-sectional structure.

Each of the organic EL devices 2 according to the first through fourth modified examples includes the high-refractive-index scattering layer 34 having a predetermined regular cross-sectional structure, which makes it possible to enhance a light scattering property. Other configurations remain the same as those of the twenty-ninth embodiment, and no repeated description will be made on the same configurations.

In the organic EL devices 2 according to the twenty-ninth embodiment and the first through fourth modified examples thereof, the light (hν) is emitted from both the surface of the substrate 10 and the surface of the high-refractive-index scattering layer 34.

With the organic EL devices 2 according to the twenty-ninth embodiment and the first through fourth modified examples thereof, it is possible to reduce or remove a surface plasmon loss by using the transparent electrode 32.

The provision of the high-refractive-index scattering layer 34 having an uneven surface on which patterns are arranged regularly makes it possible to convert a thin film mode to a substrate mode or an external mode.

Accordingly, it is possible to extract the light with the quantity corresponding to the surface plasmon loss, which is higher in proportion than other losses, and the thin film wave guide mode loss. This makes it possible to greatly enhance the light extraction efficiency.

### Thirtieth Embodiment

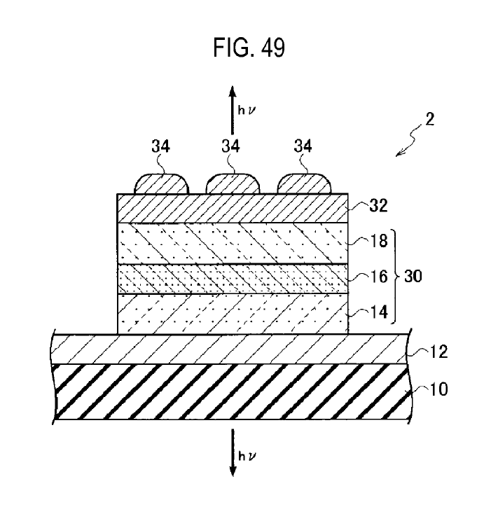

Referring to FIG. 49, an organic EL device 2 according to the thirtieth embodiment includes a high-refractive-index scattering layer 34 formed of a patterned polycrystalline organic material as a substitute for the high-refractive-index scattering layer 34 formed of a polycrystalline material employed in the twenty-ninth embodiment shown in FIG. 45. Other configurations remain the same as those of the twenty-ninth embodiment, and no repeated description will be made on the same configurations.

As the polycrystalline organic material, it is possible to use, DPB, PBD, BP1T, p-4P, and NTDA, the chemical structural formulae of which are shown in FIGS. 40 through 44.

In the organic EL device 2 according to the thirtieth embodiment, the light (hν) is emitted from both the surface of the substrate 10 and the surface of the high-refractive-index scattering layer 34.

With the organic EL device 2 according to the thirtieth embodiment, it is possible to reduce or remove a surface plasmon loss by using the transparent electrode 32.

The provision of the high-refractive-index scattering layer 34 formed of a polycrystalline material makes it possible to convert a thin film mode to a substrate mode or an external mode.

Accordingly, it is possible to extract the light with the quantity corresponding to the surface plasmon loss, which is higher in proportion than other losses, and the thin film wave guide mode loss. Thus, this makes it possible to greatly enhance the light extraction efficiency.

### Thirty-First Embodiment

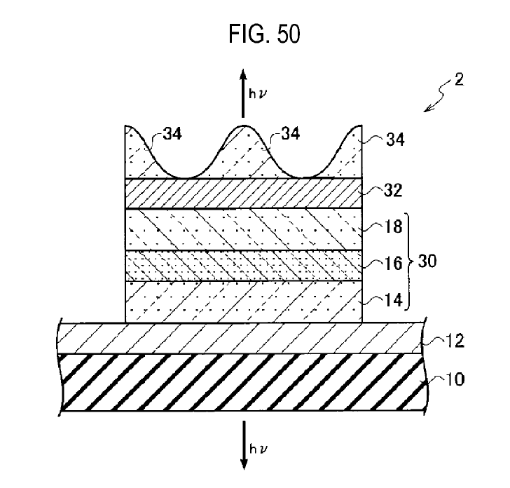

Referring to FIG. 50, an organic EL device 2 according to a thirty-first embodiment includes a high-refractive-index scattering layer 34 having a wavy structure. The structure shown in FIG. 50 may be formed by using, as the high-refractive-index scattering layer 34, an organic material having a glass transition point Tj lower than the glass transition point T of the organic EL layer 30. Other configurations remain the same as those of the twenty-eighth embodiment, and no repeated description will be made on the same configurations.

In the organic EL device 2 according to the thirty-first embodiment, the light (hν) is emitted from both the surface of the substrate 10 and the surface of the high-refractive-index scattering layer 34.

With the organic EL device 2 according to the thirty-first embodiment, it is possible to reduce or remove a surface plasmon loss by using the transparent electrode 32.

The provision of the high-refractive-index scattering layer 34 having a wavy structure makes it possible to convert a thin film mode to a substrate mode or an external mode.

Accordingly, it is possible to extract the light with the quantity corresponding to the surface plasmon loss, which is higher in proportion than other losses, and the thin film wave guide mode loss. This makes it possible to greatly enhance the light extraction efficiency.

### Thirty-Second Embodiment

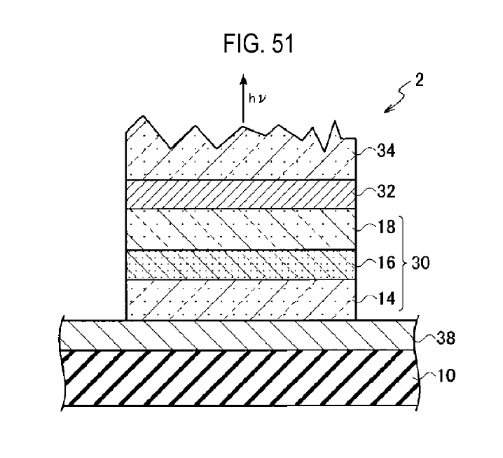

Referring to FIG. 51, an organic EL device 2 according to a thirty-second embodiment has a configuration in which the first electrode layer 12 of the twenty-eighth embodiment shown in FIG. 37 is replaced by a metal electrode layer 38. Other configurations remain the same as those of the twenty-eighth embodiment, and no repeated description will be made on the same configurations.

The metal electrode layer 38 may be made of, e.g., Ag, Al, etc.

Further, the thickness of the metal electrode layer 38 may be set such that light does not substantially pass through the metal electrode layer 38.

As shown in FIG. 51, the organic EL device 2 according to the thirty-second embodiment has a top emission configuration in which the light (hν) emitted from the light emitting layer 16 is reflected by the metal electrode layer 38 and is emitted from the high-refractive-index scattering layer 34.

With the organic EL device 2 according to the thirty-second embodiment, it is possible to reduce or remove a surface plasmon loss by using the transparent electrode 32.

The provision of the high-refractive-index scattering layer 34 makes it possible to convert a thin film mode to a substrate mode or an external mode.

Accordingly, it is possible to extract the light with the quantity corresponding to the surface plasmon loss, which is higher in proportion than other losses, and the thin film wave guide mode loss. This makes it possible to greatly enhance the light extraction efficiency.

Further, with the organic EL device 2 according to the thirty-second embodiment, it is possible to increase an aperture ratio by employing the top emission configuration in which the light emitted from the light emitting layer 16 is reflected by surface of the metal electrode layer 38.

### Thirty-Third Embodiment

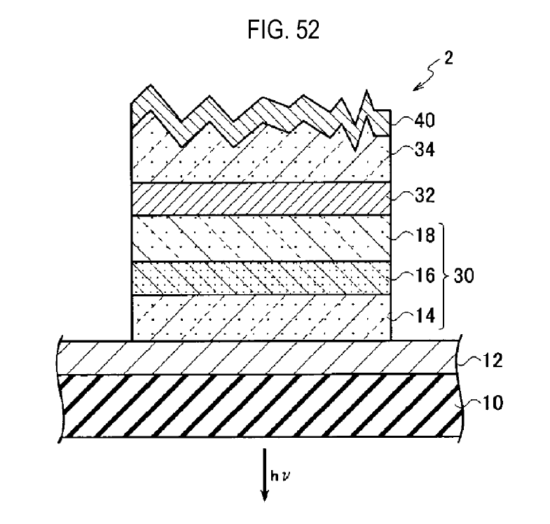

Referring to FIG. 52, an organic EL device 2 according to a thirty-third embodiment has a configuration in which a high reflectance metal layer 40 is arranged on the high-refractive-index scattering layer 34 of the twenty-eighth embodiment shown in FIG. 37. Other configurations remain the same as those of the twenty-eighth embodiment, and no repeated description will be made on the same configurations.

Examples of the high reflectance metal include Ag, Al, Mo, and Ta.

As shown in FIG. 52, the organic EL device 2 according to the thirty-third embodiment has a bottom emission configuration in which the light (hν) emitted from the light emitting layer 16 is reflected by the high reflectance metal layer 40 and is emitted from the substrate 10.

With the organic EL device 2 according to the thirty-third embodiment, it is possible to reduce or remove a surface plasmon loss by using the transparent electrode 32.

The provision of the high-refractive-index scattering layer 34 makes it possible to convert a thin film mode to a substrate mode or an external mode.

Accordingly, it is possible to extract the light with the quantity corresponding to the surface plasmon loss, which is higher in proportion than other losses, and the thin film wave guide mode loss. This makes it possible to greatly enhance the light extraction efficiency.

### Thirty-Fourth Embodiment

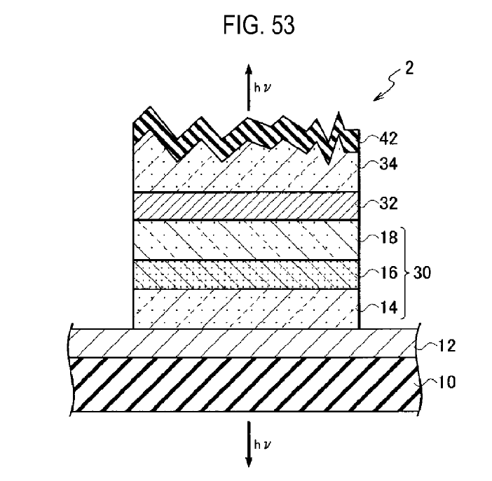

Referring to FIG. 53, an organic EL device 2 according to a thirty-fourth embodiment has a configuration in which a protective layer 42 is arranged on the high-refractive-index scattering layer 34 of the twenty-eighth embodiment shown in FIG. 37. Other configurations remain the same as those of the twenty-eighth embodiment, and no repeated description will be made on the same configurations.

The protective layer 42 is formed of a thin film made of, e.g., an inorganic material such as SiO₂ or SiN, or a predetermined organic material.

In the organic EL device 2 according to the thirty-fourth embodiment, the light (hν) is emitted from both the surface of the substrate 10 and the surface of the high-refractive-index scattering layer 34.

With the organic EL device 2 according to the thirty-fourth embodiment, it is possible to reduce or remove a surface plasmon loss by using the transparent electrode 32.

The provision of the high-refractive-index scattering layer 34 makes it possible to convert a thin film mode to a substrate mode or an external mode.

Accordingly, it is possible to extract the light with the quantity corresponding to the surface plasmon loss, which is higher in proportion than other losses, and the thin film wave guide mode loss. This makes it possible to greatly enhance the light extraction efficiency.

Further, by arranging the protective layer 42 on the high-refractive-index scattering layer 34, it is possible to avoid a situation where the high-refractive-index scattering layer 34 and the organic EL layer 30 are damaged when the organic EL layer 30, the transparent electrode 32, and the high-refractive-index scattering layer 34 are sealed with a resin, as in the thirty-fifth embodiment to be described below.

### Thirty-Fifth Embodiment

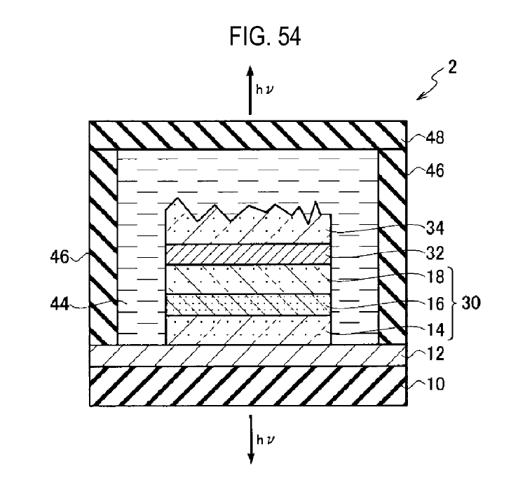

Referring to FIG. 54, an organic EL device 2 according to a thirty-fifth embodiment includes a sealing portion 46 formed on the substrate 10, a sealing plate 48 arranged on the sealing portion 46 and a filler 44 which fills a space between the sealing portion 46, the sealing plate 48, the organic EL layer 30, the transparent electrode 32, and the high-refractive-index scattering layer 34. The organic EL layer 30, the transparent electrode 32, and the high-refractive-index scattering layer 34 are sealed by the sealing portion 46 and the sealing plate 48. While the sealing portion 46 is arranged on the first electrode layer 12 positioned on the substrate 10 in FIG. 54, the sealing portion 46 may be directly arranged on the substrate 10. For example, it may be sometimes the case where some regions of the first electrode layer 12 are removed after patterning the first electrode layer 12 on the substrate 10, and then the sealing portion 46 on the substrate 10 may be arranged along the regions in which the first electrode layer 12 does not exist. Auxiliary wiring lines may be used in certain instances.

The sealing portion 46 may be made of a UV-curable resin, glass frit, etc.

The sealing plate 48 may be formed of a polymer resin substrate, glass substrate, etc.

The filler 44 may be formed of a solid or liquid resin, glass, oil, e.g., fluorine-based inert oil, or gel, or a rare gas such as a nitrogen gas, etc. The filler 44 may be transparent or cloudy.

In the organic EL device 2 according to the thirty-fifth embodiment, the light (hν) is emitted from both the surface of the substrate 10 and the surface of the high-refractive-index scattering layer 34.

In the organic EL device 2 according to the thirty-fifth embodiment, at least one of the sealing plate 48 and the substrate 10 may have an uneven surface on which patterns are arranged randomly or regularly.

### First Modified Example

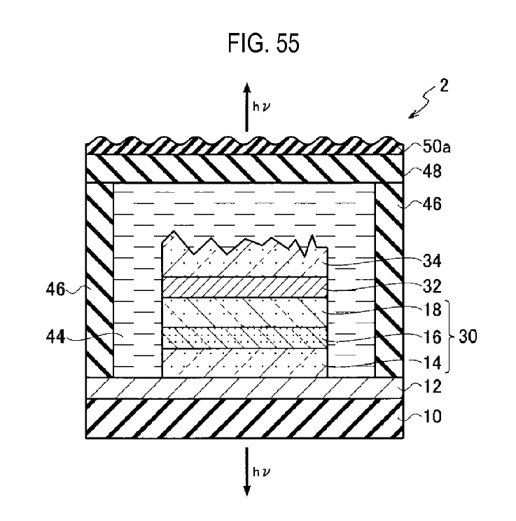

Referring to FIG. 55, an organic EL device 2 according to a first modified example of the thirty-fifth embodiment has a configuration in which a light extraction film 50a formed of a prism sheet, etc., is attached to the top surface of the sealing plate 48.

### Second Modified Example

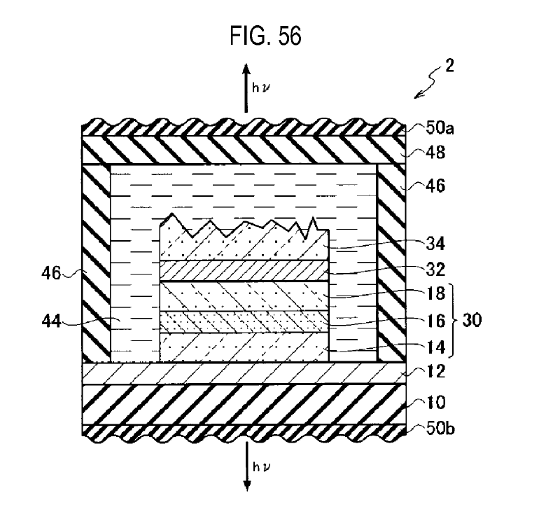

Referring to FIG. 56, an organic EL device 2 according to a second modified example of the thirty-fifth embodiment has a configuration in which light extraction films 50a and 50b formed of a prism sheet, etc., are attached to the top surface of the sealing plate 48 and the bottom surface of the rear surface of the substrate 10.

### Third Modified Example

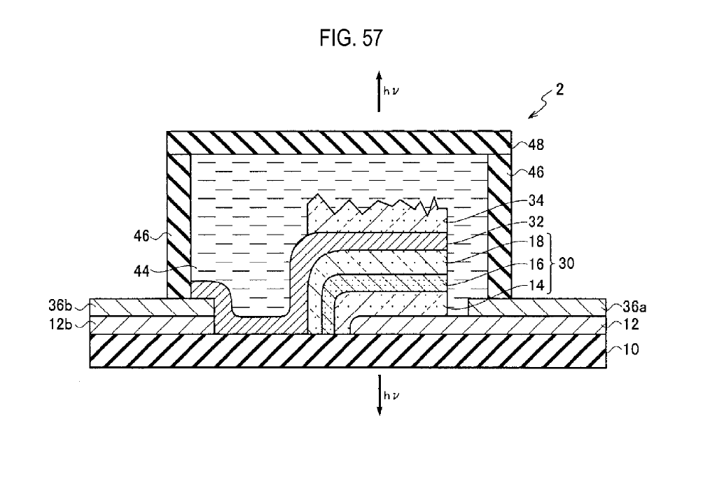

Referring to FIG. 57, an organic EL device 2 according to a third modified example of the thirty-fifth embodiment includes auxiliary wiring lines 36a and 36b.

As shown in FIG. 57, the organic EL device 2 according to the third modified example of the thirty-fifth embodiment includes a sealing portion 46 formed on the substrate 10, a sealing plate 48 arranged on the sealing portion 46, and a filler 44 filling the space between the sealing portion 46, the sealing plate 48, the organic EL layer 30, the transparent electrode 32, and the high-refractive-index scattering layer 34. The organic EL layer 30, the transparent electrode 32, and the high-refractive-index scattering layer 34 are sealed by the sealing portion 46 and the sealing plate 48. In FIG. 57, the sealing portion 46 is arranged on the first electrode layer 12 positioned on the substrate 10, the auxiliary wiring line 36a being interposed between the sealing portion 46 and the first electrode layer 12. Further, in FIG. 57, the sealing portion 46 is also arranged on a first electrode layer 12b positioned on the substrate 10 and insulated from the first electrode layer 12, the auxiliary wiring line 36b, connected to the transparent electrode 32, being interposed between the sealing portion 46 and the first electrode layer 12b. Just like in the first modified example, the organic EL device 2 according to the third modified example may have a configuration in which a light extraction film (not shown) formed of a prism sheet, etc. is attached to the front surface of the sealing plate 48. Further, just like in the second modified example, the organic EL device 2 according to the third modified example may have a configuration in which light extraction films (not shown) formed of a prism sheet, etc. are attached to the front surface of the sealing plate 48 and the rear surface of the substrate 10.

With the thirty-fifth embodiment and the first through third modified examples thereof, it is possible to enhance the durability of the organic EL device 2 because the organic EL layer 30, the transparent electrode 32, and the high-refractive-index scattering layer 34 are sealed and the filler 44 fills the space.

With the first through third modified examples of the thirty-fifth embodiment, the provision of the light extraction films 50a and 50b makes it possible to have the light (hν) efficiently emitted from the sealing plate 48 or the sealing plate 48 and the substrate 10.

In the thirty-fifth embodiment and the first through third modified examples thereof, it may be possible to employ a configuration in which a protective layer 42 is arranged on the high-refractive-index scattering layer 34 as shown in FIG. 53. The protective layer 42 may restrain the high-refractive-index scattering layer 34 and the filler 44 from making a chemical reaction with each other.

With the embodiments described above, it is possible to provide an organic EL device capable of simultaneously optimizing the internal quantum efficiency and the light extraction efficiency.

### Other Embodiments

While the present disclosure has been described using the embodiments and the modified examples thereof, it should be appreciated that the present disclosure is not limited to the description and the drawings which form a part of the present disclosure. It will be apparent to those skilled in the art that many different alternative embodiments, examples, and management technologies may be derived from the present disclosure.

For example, the organic EL layer 30 may be a multi-photon emission type organic EL layer having one or more electric charge generation layers and two or more light emitting layers.

It goes without saying that the present disclosure embraces many different embodiments not disclosed herein. Accordingly, the technical scope of the present disclosure is decided by only the subject matters defined in the claims.

The organic EL devices of the present disclosure may be applied to a high-illuminance organic EL lighting field, a high-illuminance organic EL display field, and other like fields.

With the present disclosure, it is possible to provide an organic EL device capable of simultaneously optimizing the internal quantum efficiency and the light extraction efficiency.

While certain embodiments have been described, these embodiments have been presented by way of example only, and are not intended to limit the scope of the disclosures. Indeed, the novel devices described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. An organic EL device, comprising:
a substrate;
a first electrode layer arranged on the substrate;
an organic EL layer arranged on the first electrode layer;
an optical property adjusting layer arranged on the organic EL layer; and
a second electrode layer arranged on the optical property adjusting layer.

2. The device of claim 1, further comprising a property separation layer arranged on the organic EL layer, the optical property adjusting layer arranged on the property separation layer.

3. An organic EL device, comprising:
a substrate;
a first electrode layer arranged on the substrate;
an optical property adjusting layer arranged on the first electrode layer;
an organic EL layer arranged on the optical property adjusting layer; and
a second electrode layer arranged on the organic EL layer.

4. The device of claim 3, further comprising a property separation layer arranged on the optical property adjusting layer, the organic EL layer arranged on the property separation layer.

5. The device of claim 1, wherein the optical property adjusting layer is an organic material layer transparent in a visible light region.

6. The device of claim 2, wherein the property separation layer is an electric charge generation layer or a transparent electrode layer.

7. The device of claim 1, wherein the optical property adjusting layer includes a hole-transporting-material layer or an electron-transporting-material layer.

8. The device of claim 2, wherein the property separation layer is an electric charge generation layer, a transparent electrode layer, or a conductive thin film layer.

9. The device of claim 1, wherein the second electrode layer is a metal film having high reflectance.

10. The device of claim 1, wherein the optical property adjusting layer is transparent in a visible light region and has a light scattering property.

11. The device of claim 10, wherein the optical property adjusting layer is a polycrystalline organic material layer.

12. The device of claim 1, wherein an interface between the optical property adjusting layer and the second electrode layer has an uneven surface on which patterns are arranged randomly.

13. The device of claim 4, wherein an interface between the optical property adjusting layer and the property separation layer has an uneven surface on which patterns are arranged randomly.

14. The device of claim 3, wherein an interface between the optical property adjusting layer and the first electrode layer has an uneven surface on which patterns are arranged randomly.

15. The device of claim 12, wherein the second electrode layer is partially in contact with the property separation layer.

16. The device of claim 2, wherein the optical property adjusting layer is patterned into a predetermined pattern structure and the second electrode layer is partially in contact with the property separation layer.

17. The device of claim 16, wherein the pattern structure has one of a circular pattern, a square pattern, a circular pattern forming a triangle, and a rectangular pattern.

18. The device of claim 1, wherein the optical property adjusting layer has a glass transition point lower than a glass transition point of the organic EL layer.

19. The device of claim 1, wherein the optical property adjusting layer has a thickness of 200 nm or less.

20. The device of claim 11, wherein the polycrystalline organic material layer has a thickness substantially equal to or less than a grain size.

21. The device of claim 1, wherein the optical property adjusting layer is doped with a metal.

22. The device of claim 1, wherein the optical property adjusting layer is doped with a material capable of forming a charge-transfer complex.

23. The device of claim 1, wherein major electrodes are selected from the first electrode layer and the second electrode layer, respectively.

24. The device of claim 2, wherein major electrodes are selected from the first electrode layer and the property separation layer, respectively.

25. The device of claim 2, wherein major electrodes are selected from the first electrode layer and the property separation layer short-circuited to the second electrode layer, respectively.

26. The device of claim 4, wherein major electrodes are selected from the second electrode layer and the property separation layer, respectively.

27. The device of claim 4, wherein major electrodes are selected from the second electrode layer and the property separation layer short-circuited to the first electrode layer, respectively.

28. The device of claim 1, wherein a bulk refractive index of a material forming the optical property adjusting layer in at least a portion of a wavelength region of 380 nm to 780 nm is greater than one of a refractive index of the substrate, the organic EL layer, the first electrode layer, or the second electrode layer.

29. An organic EL device, comprising:
a substrate;
a first electrode layer arranged on the substrate;
an organic EL layer arranged on the first electrode layer;
a second electrode layer arranged on the organic EL layer; and
a high-refractive-index scattering layer arranged on the second electrode layer.

30. The organic EL device of claim 29, wherein the high-refractive-index scattering layer is an organic material layer or a polycrystalline organic material layer transparent in a visible light region.

31. The organic EL device of claim 29, wherein the second electrode layer is a transparent electrode layer or a metal layer.

32. The organic EL device of claim 29, wherein the high-refractive-index scattering layer has an uneven surface on which patterns are arranged randomly.

33. The organic EL device of claim 29, wherein the high-refractive-index scattering layer is patterned into a predetermined pattern structure.

34. The organic EL device of claim 33, wherein the pattern structure has one of a circular pattern, a square pattern, a circular pattern forming a triangle, and a rectangular pattern.

35. The organic EL device of claim 29, wherein the high-refractive-index scattering layer has grain boundaries.

36. The organic EL device of claim 29, wherein the first electrode layer is a metal electrode layer.

37. The organic EL device of claim 29, further comprising a high reflectance metal film arranged on the high-refractive-index scattering layer.

38. The organic EL device of claim 29, further comprising a protective layer arranged on the high-refractive-index scattering layer.

39. The organic EL device of claim 29, further comprising:
a sealing portion formed on the substrate;
a sealing plate arranged on the sealing portion;
a filler configured to fill a space between the sealing portion, the sealing plate, the organic EL layer, the second electrode layer and the high-refractive-index scattering layer,
wherein the organic EL layer, the second electrode layer and the high-refractive-index scattering layer are sealed by the sealing portion and the sealing plate.

40. The organic EL device of claim 39, wherein the filler is formed of a solid or liquid resin, glass, oil, gel or a rare gas.

41. The organic EL device of claim 39, further comprising:
a light extraction film arranged on a surface of at least one of the sealing plate and the substrate.

42. The organic EL device of claim 39, wherein at least one surface of the sealing plate and the substrate has uneven shape on which patterns are arranged randomly or regularly.

43. The device of any one of claims 29, wherein the high-refractive-index scattering layer has a thickness of 200 nm or less.

44. The device of claim 35, wherein the high-refractive-index scattering layer has a thickness substantially equal to or less than a grain size.

45. The device of claim 29, wherein a bulk refractive index of a material forming the high-refractive-index scattering layer in at least a portion of a wavelength region of 380 nm to 780 nm is greater than a refractive index of the substrate, the organic EL layer, the first electrode layer, or the second electrode layer.

46. The device of claim 1, wherein the organic EL layer is a multi-photon emission type organic EL layer including one or more electric charge generation layers and two or more light emitting layers.
